(19) United States
(12) Patent Application Publication
(10) Pub. No.: US 2005/0193320 A1
(43) Pub. Date: Sep. 1, 2005

(54) Methods and apparatus for improving performance of information coding schemes

(75) Inventors: Nedeljko Varnica, Cambridge, MA (US); Aleksandar Kavcic, Cambridge, MA (US); Marc Fossorier, Honolulu, HI (US)

Correspondence Address: LOWRIE, LANDO & ANASTASI, RIVERFRONT OFFICE, ONE MAIN STREET, ELEVENTH FLOOR, CAMBRIDGE, MA, 02142, US

(73) Assignees: President and Fellows of Harvard College, Cambridge, MA (US); University of Hawaii, Honolulu, HI (US)

(21) Appl. No.: 10/774,763

(22) Filed: Feb. 9, 2004

(51) Int. Cl. H03M 13/00; G06F 11/00

(52) U.S. Cl. 714/800

(57) ABSTRACT

Various modifications to conventional information coding schemes that result in an improvement in one or more performance measures for a given coding scheme. Some examples are directed to improved decoding techniques for linear block codes, such as low-density parity-check (LDPC) codes. In one example, modifications to a conventional belief-propagation (BP) decoding algorithm for LDPC codes significantly improve the performance of the decoding algorithm so as to more closely approximate that of the theoretically optimal maximum-likelihood (ML) decoding scheme. BP decoder performance generally is improved for lower code block lengths, and significant error floor reduction or elimination may be achieved for higher code block lengths. In one aspect, significantly improved performance of a modified BP algorithm is achieved while at the same time essentially maintaining the benefits of relative computational simplicity and execution speed of a conventional BP algorithm as compared to an ML decoding scheme. In another aspect, modifications for improving the performance of conventional BP decoders are universally applicable to “off the shelf” LDPC encoder/decoder pairs. Furthermore, the concepts underlying the various methods and apparatus disclosed herein may be more generally applied to various decoding schemes involving iterative decoding algorithms and message-passing on graphs, as well as coding schemes other than LDPC codes to similarly improve their performance. Exemplary applications for improved coding schemes include wireless (mobile) networks, satellite communication systems, optical communication systems, and data recording and storage systems (e.g., CDs, DVDs, hard drives, etc.).

### FIELD OF THE INVENTION

The present disclosure relates generally to various modifications to conventional information coding schemes that result in an improvement in one or more performance measures for a given coding scheme. In particular, some exemplary implementations disclosed herein are directed to improved decoding techniques for linear block codes, such as low-density parity-check (LDPC) codes.

### BACKGROUND

In its most basic form, an information transfer system may be viewed in terms of an information source, an information destination, and an intervening path or “channel” between the source and the destination. When information is transmitted from the source to the destination, it often suffers distortions from its original form due to imperfections in the channel. These imperfections generally are referred to as noise or interference.

To accurately recover the original source information at the destination, data protection or “coding” schemes conventionally are employed in many information transfer systems to detect and correct transmission errors due to noise. In such coding schemes, the original information is encoded at the source before being transmitted over some path to the destination. At the destination, adequate decoding techniques are implemented to effectively recover the original information.

Information coding schemes are well known in the relevant literature. The history of information coding dates back to the late 1940s, where pioneering research in this area resulted in reliable communication of information over an unreliable or “noisy” transmission channel. In one conventional analytical framework, a communication channel may be viewed in terms of input information, output information, and a probability that the output information does not match the input information (e.g., due to noise induced by the channel). In this context, the “capacity” of a communication channel generally is defined as a maximum rate of information transmission on the channel below which reliable transmission is possible, given the bandwidth of the channel and noise or interference conditions on the channel. Based on this framework, one of the central themes underlying information coding theory is that if the rate of information transmission (i.e., the “code rate,” discussed further below) is less than the capacity of the communication channel, reliable communication can be achieved based on carefully designed information encoding and decoding techniques.

Two common archetypes of digital information transfer systems are communications systems and data storage systems. FIG. 1 illustrates a generalized block-diagram model for such systems. As shown in FIG. 1, in a digital information transfer system, a digital information source 30 provides a binary information sequence 32 (i.e., a sequence of bits each having either a logic high or logic low level), denoted as u. An encoder 34 transforms the information sequence 32 into an encoded sequence 36, denoted as x. In most instances, x also is a binary sequence, although in some applications non-binary codes have been employed.

In FIG. 1, a physical communication channel over which encoded information is transmitted, or a storage medium on which encoded information is to be recorded, is indicated generally by the reference number 40. Typical examples of transmission channels include, but are not limited to, various types of wire and wireless links such as telephone or cable lines, high-frequency radio links, telemetry links, microwave links, satellite links and the like. Typical examples of storage media include, but are not limited to, core and semiconductor memories, magnetic tapes, drums, disks, optical memory units, and the like. Each of these examples of transmission channels and storage media is subject to various types of noise disturbances that can corrupt information.

Discrete symbols of encoded information, such as the constituents of the encoded sequence x, generally are not suitable for transmission over a channel or for recording on a storage medium. Accordingly, as illustrated in FIG. 1, a modulator or writing unit 38 transforms each symbol of the encoded sequence x into a waveform of some finite duration which is suitable for transmission on the communication channel or recording on the storage medium. This waveform enters the channel or storage medium and, as mentioned above, may be corrupted by noise in the process.

FIG. 1 also illustrates a demodulator or reading unit 42 that processes each waveform either received over the channel or read from the storage medium, together with any noise that may have been induced by the channel/storage medium 40. The demodulator/reading unit 42 provides an output or received sequence 48, denoted as r. In FIG. 1, the modulator/writing unit 38, the channel/storage medium 40, and the demodulator/reading unit 42 are grouped together for purposes of illustration as a “coding channel” 44. In this manner, the coding channel 44 may be viewed more generally as accepting as an input the encoded information sequence x, adding to the encoded sequence some error sequence 46, denoted as e, and providing as an output a received sequence r, such that r=x+e. It should be appreciated that while for binary sequences x the individual elements of the sequence are bits representing logic high or logic low levels, the elements of an error sequence e generally may have virtually any real value, as the noise on a given channel may have a variety of values at any given time.

In the system of FIG. 1, a decoder 50 in turn transforms the received sequence r into a binary sequence 52, denoted as û and referred to as an “estimated information sequence.” In particular, the decoder 50 is configured to implement a decoding scheme that is complimentary to the encoding scheme employed by the encoder 34 (the information transmission system is implemented with a matched encoder/decoder pair). The decoding scheme often also takes into consideration expected noise characteristics of the coding channel 44; for example, in some cases the decoder 50 first determines an estimated code sequence 51, denoted as \hat{x}, based on the received sequence r and the expected noise characteristics of the channel. The decoder then determines the estimated information sequence û based on the estimated code sequence \hat{x}. Ideally, the estimated information sequence û is a replica of the original information sequence u, although any noise e induced by the coding channel 44 may occasionally cause some decoding errors. Finally, the estimated information sequence û, preferably error-free, is passed on to some information destination 54 to complete the transfer of information that originated at the source 30.

The ability to minimize decoding errors is an important performance measure of an information transmission system as modeled in FIG. 1. To this end, two different types of conventional coding schemes in common use include “block” coding schemes and “convolutional” coding schemes. For purposes of the present disclosure, the focus primarily is on block coding schemes. However, one of skill in the art would readily appreciate that many of the concepts discussed throughout the present disclosure may be applied to convolutional coding schemes as well as block coding schemes.

In block coding schemes, the encoder 34 shown in FIG. 1 typically groups the binary information sequence 32 provided by the source 30 into blocks of bits represented as vectors, each vector u having some number k of bits (i.e., u=[u₀, u₁, u₂ . . . . uₖ₋₁]). In this manner, a vector u often is referred to as an “information message” having a length k. It should be appreciated that, given information messages u each having k bits, a total of 2^{k} distinct information messages are possible in the information transmission system.

The encoder 34 then transforms each information message u into a corresponding vector x of discrete symbols that form part of the encoded sequence 36. The vector x generally is referred to as a “code word.” In most instances, the code word x also is a binary sequence having some number N of bits, where N>k (i.e., x=[x₀, x₁, x₂ . . . . x_{N-1}], where the code word x is longer than the original information message u). In any case, there is a one-to-one correspondence between each information message u and a code word x, such that a total of 2^{k} different code words each of length N make up a “block code.” The “code rate” R of such a block code is defined as R=k/N.

One important subclass of block codes is referred to as “linear’ block codes. A binary block code is defined as “linear” if the modulo-2 sum (i.e., logic exclusive OR function) of any two code words x₁ and x₂ also is a code word. This implies that it is possible to find k linearly independent code words having length N such that every code word in the block code is a linear combination of these k code words. These k linearly independent code words from which all of the other code words may be generated are commonly denoted in the literature as g₀, g₁, g₂ . . . . gₖ₋₁. Using these particular code words, the encoder 34 shown in FIG. 1 may be implemented as a “generator matrix” G having k rows and N columns (where each row of the generator matrix G is formed by one of the k linearly independent code words g₀, g₁, g₂ . . . . gₖ₋₁, such that a given code word x is defined by the dot product x=u·G. Stated differently, to generate any given code word x, the k individual bits of a given original information message u provide the binary “weights” for the linear combination of the k linearly independent code words that form the generator matrix G.

For purposes of initially illustrating some basic concepts underlying the encoding and decoding of linear block codes, a subclass of linear block codes referred to in the literature as linear “systematic” block codes is considered first below. Systematic block codes have been considered for some practical applications based on their relative simplicity and ease of implementation as compared to more general types of block codes. It should be appreciated, however, that the concepts discussed herein in connection with systematic codes may be applied more broadly to various types of block codes other than systematic codes; again, the discussion of these codes here is primarily to facilitate an understanding of some concepts that are germane to various classes of block codes.

For linear systematic binary block codes, each code word x includes the original information message u, plus some extra bits. FIG. 2 shows an example of such a code word x. More specifically, the generator matrix G is constructed such that each generated code word x includes k bits corresponding to the original information message u, and N-k extra bits 56. The particular format of the generator matrix G for the systematic code specifies that each of these extra bits is a linear sum (modulo-2) of some unique combination of the individual bits in the original information message u. These extra bits 56 of the systematic code often are referred to as “parity-check bits.”

In some sense, the parity-check bits of the systematic block code example represent the underlying premise of coding techniques; namely, the extra number of bits in a code word x provide the capability of correcting for possible decoding errors due to noise induced by the coding channel 44. More generally, for broader classes of linear block codes in addition to systematic codes, it is the presence of some number of extra bits beyond the original number of bits in the information message u that provide for decoding error detection and error correction capability. This is the case whether or not the original information message u is preserved “in tact” in the code word x.

Another important matrix associated with every linear block code (systematic or otherwise) is referred to as a “parity-check matrix,” typically denoted in the literature as H. The parity-check matrix H has N-k linearly independent rows and N columns, and is defined such that the matrix dot product G·H^{T} generates a zero matrix. More specifically, any vector in the row space of G is orthogonal to the rows of H and any vector that is orthogonal to the rows of H is in the row space of G. This also implies that the dot product x·H^{T} for any code word x generates an N-k element zero vector (i.e., a vector having a zero bit for every parity-check bit of a given code word x). This zero vector result of the dot product x·H^{T} is denoted as z, and is commonly referred to as a “parity-check vector.” Again, it should be understood that the parity-check vector z is a zero vector which verifies that a valid code word x has been operated on by the parity-check matrix H.

To further illustrate the concepts of the parity-check matrix and the parity-check vector, consider a linear systematic block code in which k=4 (i.e., the original information messages u are four bits long) and N=7 (i.e., the code words x are seven bits long). It should be appreciated that this is a relatively simple code that is discussed here primarily for purposes of illustration, and that codes conventionally implemented at present in various applications are significantly more complex (e.g., N on the order of 1000 bits).

From the discussion above and the form of the exemplary code word x illustrated in FIG. 2, it can be readily seen that for an N=7, k=4 linear systematic block code, each code word includes N-k=3 parity-check bits. Hence, the parity-check vector z has three elements (i.e., one element for each parity-check bit).

Consider the following exemplary parity-check matrix H formulated for this N=7, k=4 coding scheme:

$$H = [ \begin{matrix}1 & 0 & 0 & 1 & 0 & 0 & 1 \\ 0 & 1 & 0 & 1 & 0 & 1 & 0 \\ 0 & 0 & 1 & 1 & 1 & 1 & 1\end{matrix} ] . \qquad ( 1 )$$

Performing the dot product x·H^{T} for some code word x yields a set of relationships that determine the elements of the parity-check vector z:

$$z = [ \begin{matrix}{z}_{0} & {z}_{1} & {z}_{2}\end{matrix} ] = [ \begin{matrix}{x}_{0} & {x}_{1} & {x}_{2} & {x}_{3} & {x}_{4} & {x}_{5} & {x}_{6}\end{matrix} ] \cdot [ \begin{matrix}1 & 0 & 0 \\ 0 & 1 & 0 \\ 0 & 0 & 1 \\ 1 & 1 & 1 \\ 0 & 0 & 1 \\ 0 & 1 & 1 \\ 1 & 0 & 1\end{matrix} ] \\ where \text{:} \\ {z}_{0} = {x}_{0} + {x}_{3} + {x}_{6} \\ {z}_{1} = {x}_{1} + {x}_{3} + {x}_{5} \\ {z}_{2} = {x}_{2} + {x}_{3} + {x}_{4} + {x}_{5} + {x}_{6} . \qquad ( 2 )$$

From the foregoing set of equations (2), it can be readily verified that each bit of the parity-check vector z is a sum of a unique combination of bits of the code word x. By definition of the linear block code, each of these equations yields a zero result (i.e., z₀=z₁=z₂=0) for a valid code word x.

Based on the concepts discussed above, one of the salient aspects of a given linear block code is that it is completely specified by either its generator matrix G or its parity-check matrix H. Accordingly, for linear block codes, the decoder 50 shown in FIG. 1 is implemented in part by applying the parity-check matrix H to information derived from a received vector r to begin the process of attempting to recover a valid code word. As discussed above, the received vector r may be viewed figuratively as the vector sum of the transmitted binary code word x and an error vector e of real values. In this sense, any element of the error vector e that is not zero constitutes a transmission error (i.e., the received vector r is a replica of the code word x only if e=0, since r=x+e).

As discussed above, the decoder 50 generally first operates on the received vector r (which may include real values due to the noise vector e) to generate an estimated binary code word \hat{x} based on the expected noise characteristics of the coding channel 44. The decoder then generates what is commonly referred to as the “syndrome” s of the estimated code word \hat{x}, given by s=\hat{x}·H^{T}. Referring again to the equations (2) above, the syndrome s is calculated essentially by replacing the indicated bits of the code word x in the equations with the corresponding bits of the estimated code word \hat{x}; in this manner, the parity-check vector elements z₀, z₁ and z₂ are replaced with the syndrome elements s₀, s₁, and s₂. Based on the description of the parity-check matrix H immediately above, the syndrome s=0 if and only if \hat{x} is some valid code word (e.g., if \hat{x}=x, then s=z). Otherwise, a nonzero syndrome s indicates that \hat{x} is not amongst the possible valid code words of the block code, and hence the presence of errors in the received vector r has been detected by the decoder 50.

If a received vector r processed by the decoder 50 yields a zero syndrome s, in one sense the decoder may assume that the received vector has been successfully decoded without error. Thus, the decoder 50 may provide as an output the estimated information message û based on the successfully decoded received vector r (for linear systematic block codes, the estimated information message û is a k bit portion of the estimated code word \hat{x}). Again, this estimated information message ideally is a replica of the original information message u.

It is noteworthy, however, that there are certain errors that are not detectable according to the above decoding scheme. For example, consider an error vector e that is identical to some nonzero code word x′ of the block code. Based on the definition of a linear block code, the sum of any two code words yields another code word; accordingly, adding to a transmitted code word x an error vector e that happens to replicate a nonzero code word x′ generates a received vector r that is another valid code word x″ (i.e., r=x+x′=x″). The decoder described immediately above will generate a zero syndrome s for this received vector and determine that the received vector r represents some valid code word of the block code; however, it may not represent the code word x that was in fact transmitted by the encoder. Hence, a decoding error results. In this manner, an error vector e that replicates some valid code word of the block code constitutes an undetectable error pattern.

In view of the foregoing, various conventional linear block codes and encoding and decoding schemes for such codes have been developed to enhance the robustness of the information transmission system shown in FIG. 1 against transmission errors. Many such schemes employ probabilistic algorithms, in part based on expected characteristics of the coding channel 44, so as to reduce and preferably minimize decoding errors.

For example, some such schemes operate under the premise that a decoder receiving a vector r can determine the most likely code word that was sent based on a conditional probability, i.e., the probability of code word x being sent given the estimated code word \hat{x} (based on the observed received vector r and the channel characteristics), or P[x|\hat{x}]. This may be accomplished by listing all of the 2^{k} possible code words of the block code, and calculating the conditional probability for each code word based on the estimated code word \hat{x}. The code word or words that yield the maximum conditional probability then are the most likely candidates for the transmitted code word x. This type of decoder conventionally is referred to as a “maximum likelihood” (ML) decoder.

With respect to practical implementation in a “real world” application, a decoder based on an ML algorithm is quite unwieldy and time consuming from a computational standpoint, especially for large block codes. Accordingly, ML decoders remain essentially a theoretical methodology and without practical use. However, ML decoders provide the performance benchmark for information transmission systems; in particular, it has been shown in the literature that for any code rate R less than the capacity of the coding channel, the probability of decoding error of an ML decoder for optimal codes goes to zero as the block length N of the code goes to infinity.

An interesting sub-class of linear block codes that in some cases provide less optimal but significantly less algorithmically intensive coding/decoding schemes includes low-density parity-check (LDPC) codes. By definition, LDPC codes are linear block codes that have “sparse” parity-check matrices H (generally speaking, a sparse parity-check matrix has an appreciable number of zero elements). This implies that the set of equations that generate the elements of the parity-check vector z (and likewise, the syndrome s for a given estimated code word \hat{x} based on the received vector r) do not involve significant numbers of code word bits in the calculation (e.g., see the set of equations (2) given above).

Accordingly, a decoder that employs a sparse parity-check matrix generally is less algorithmically intensive than one that employs a denser parity-check matrix. Hence, in one respect, although LDPC codes can be effectively decoded using the theoretically optimal maximum-likelihood (ML) technique discussed above, these codes also provide for other less complex and faster (i.e., more practical and efficient) decoding techniques, albeit with suboptimal results as compared to ML decoders.

One common tool used to illustrate the basic architecture underlying some conventional LDPC decoding techniques (and the benefits of employing sparse parity-check matrices) is referred to as a “bipartite graph.” FIG. 3 shows an example of such a bipartite graph 58 based on the parity-check matrix H given above in equation (1). Again, it should be appreciated that the graph illustrated in FIG. 3 is a relatively simple example provided primarily for purposes of illustrating some basic concepts germane to this disclosure. Typically, however, bipartite graphs representing actual LDPC code implementations are appreciably more complex, and generally are not based on a systematic code structure.

The bipartite graph of FIG. 3 includes a plurality of “check” nodes 60 and a plurality of “variable” nodes 62. Each check node corresponds essentially to one of the elements of the parity-check vector z whereas each variable node corresponds essentially to a bit of a code word x (or, more precisely, a bit of an estimated code word \hat{x} derived from a received vector r to be evaluated by the decoder). Accordingly, based on the exemplary block code defined by the parity-check matrix H given in equation (1), the bipartite graph 58 shown in FIG. 3 includes three check nodes c₁, c₂ and c₃ (corresponding respectively to z₀, z₁ and z₂) and seven variable nodes v₁-v₇ (corresponding respectively to x₀, x₁, x₂ . . . . x₆).

In FIG. 3, the variable nodes 62 are connected to the check nodes 60 of the bipartite graph by a set of “edges” 64, wherein the particular connections made by the edges are defined by the equations (2) that generate the parity-check vector z. For example, referring again to the equations (2) given above, the check node c₁, (corresponding to z₀) is connected to v₁ (corresponding to x₀), v₄ (corresponding to x₃) and v₇ (corresponding to x₆). Similarly, the check node c₂ (corresponding to z₁) is connected to V₂ (corresponding to x₁), V₄ (corresponding to x₃) and v₆ (corresponding to x₅). Finally, the check node c₃ (corresponding to Z₂) is connected to V₃ (corresponding to x₂), v₄ (corresponding to x₃), v₅ (corresponding to x₄), V₆ (corresponding to x₅) and v₇ (corresponding to x₆).

In one sense, the check nodes 60 may be viewed as processors that receive as inputs information from particular variable nodes, corresponding to particular bits of the code word as prescribed by the equations (2), so as to evaluate the elements of the parity-check vector z. With this in mind, it is worth noting at this point that every edge 64 in the bipartite graph 58 shown in FIG. 3 represents a computational input/output and results from the presence of a nonzero element in the parity-check matrix H given in equation (1). Hence, once again, the sparse parity-check matrix of an LDPC code results in a bipartite graph having relatively fewer edges, and a decoder with conceivably less computational complexity.

A general class of decoding algorithms for LDPC codes, based on the exemplary bipartite graph architecture illustrated in FIG. 3, commonly are referred to as “message passing algorithms.” These are iterative algorithms in which, during each iteration, “messages” 66 are passed along the edges 64 between the check nodes 60 and the variable nodes 62. In these algorithms, each of the check nodes and variable nodes may be viewed figuratively as a processor or computation center for processing the passed messages 66.

More specifically, for a given iteration of an LDPC message passing decoding algorithm based on the bipartite graph architecture shown in FIG. 3, a message sent from a given variable node vᵢ to a given check node cⱼ is computed at the variable node vᵢ based on an observed value at the variable node vᵢ (e.g., the value of the corresponding bit based on the received vector r) and earlier messages passed to the variable node vᵢ during a previous iteration from other check nodes C_{k≠j}. Stated differently, an important aspect of these algorithms is that a message sent from a variable node vᵢ to a check node cⱼ wmust not take into account the message sent in the previous iteration from the check node cⱼ to the variable node vᵢ, so as to avoid any “biasing” of information (this is sometimes referred to in the literature as an “independence assumption”). This same concept holds for a message passed from a check node cⱼ to a variable node vᵢ during a given iteration.

One important subclass of message passing algorithms is the “belief propagation” (BP) algorithm. In a BP algorithm, the messages passed along the edges of the bipartite graph are based on probabilities, or “beliefs.”

More specifically, a BP algorithm is initialized with the variable nodes 62 (e.g., shown in FIG. 3) respectively containing values based on the probability that a particular bit of an estimated code word \hat{x} (at a corresponding variable node vᵢ) has either a logic high or logic low state, given the received vector r and a-priori probabilities relating to the coding channel. During each subsequent iteration, the message passed from a given variable node vᵢ to a check node cⱼ is based on this probability derived from the received vector r, and all the probabilities communicated to vᵢ in the prior iteration from check nodes other than cⱼ. On the other hand, a message passed from a check node cⱼ to a variable node vᵢ during a given iteration is based on the probability that vᵢ has a certain value given all the probabilities passed to cⱼ in the previous iteration from variable nodes other than vᵢ.

In conventional BP decoder implementations for LDPC codes, the probability-based messages passed between check nodes and variable nodes typically are expressed in terms of “likelihoods,” or ratios of probabilities, mostly to facilitate computational simplicity (moreover, these likelihoods may be expressed as log-likelihoods to further facilitate computational simplicity). FIG. 4 illustrates a more generalized bipartite graph architecture 68 which may be used to represent a BP decoder, in which some additional notation is introduced to describe the elements of the graph and the messages passed between the nodes of the graph.

The graph 68 of FIG. 4 may be represented notationally by B=(V, E, C), where B denotes the overall graph structure, V denotes the set of variable nodes 62 (V={v₁, v₂ . . . v_{N}}), C denotes the set of check nodes 60 (C={c₁, c₂ . . . c_{N-k}}) and E denotes the Set of edges 64 connecting V and C. A given set of messages associated with the graph after a given number of decoding iterations may be denoted as M={V, C, O}, where V denotes the set of messages transmitted from the variable nodes 62 to the check nodes 60, and C denotes the set of messages transmitted from the check nodes 60 to the variable nodes 62. As discussed above in connection with FIG. 3, these messages are denoted with the reference numeral 66. The set of messages O={O(v₁), O(v₂), . . . O(v_{N})}, denoted by the reference numeral 67 in FIG. 4, represents the values input to the BP decoder based on the received vector r (e.g., the channel-based a priori log-likelihoods, given the received vector r). For example, given an Additive White Gaussian Noise (AWGN) coding channel with the noise standard deviation σ, a particular element of the message set O is given as O(vᵢ)=2rᵢσ₂, where σ is a corresponding element of the received vector r.

In a generalized conventional BP algorithm as represented in the graph of FIG. 4, the actual computations performed at the check nodes 60 and variable nodes 62 to generate the messages 66 are well-established in the literature, and beyond the scope of the present disclosure. Rather, the underlying premise of a conventional BP algorithm that facilitates an understanding of the concepts developed later in this disclosure is as follows: the BP algorithm iteratively determines likelihoods for the bits of an estimated code word \hat{x}, based on a received vector r (or more precisely, based on the set of messages O input at the variable nodes 62) and the particular interconnection of the edges 64 of the bipartite graph 68 as defined by the parity-check matrix H for a given LDPC code. Again, the information passed along the edges of the bipartite graph between check nodes 60 and variable nodes 62 relates to the likelihoods for the states of the respective bits of the estimated code word \hat{x}.

In practice, a conventional BP algorithm may be executed for some predetermined number of iterations or until the passed likelihood messages 66 are close to certainty, whichever occurs first. At that point in the algorithm, an estimated code word \hat{x} is calculated based on the likelihoods present at the variable nodes 62. The validity of this estimated code word \hat{x} is then tested by calculating its syndrome s (e.g., see equations (2) above). If the syndrome s equals the parity-check vector z (i.e., all zero elements), the BP decoding algorithm is said to have successfully converged to yield a valid code word. Otherwise, if any element of the syndrome s is non-zero, the algorithm is said to have failed and yields a decoding error.

One significant practical aspect of a BP algorithm is its running or execution time. Based on the description above, during execution a BP algorithm can be viewed as “traversing the edges” of the bipartite graph. Since the bipartite graph for LDPC codes is said to be “sparse” (based on a sparse parity-check matrix H), the number of edges traversed by the BP algorithm is relatively small; hence, the computational time for the BP algorithm may be appreciably less than for a theoretically optimal maximum likelihood (ML) approach as discussed earlier (which is based on numerous conditional probabilities corresponding to every possible code word of a block code).

However, as discussed above, while a BP decoder may be more practically attractive than an ML decoder, a tradeoff is that conventional BP decoding generally is less “powerful” than (i.e., does not perform as well as) ML decoding (again, which is considered as theoretically optimal). More specifically, it is well-established in the literature that the performance of conventional BP decoders generally is not as good as the performance of ML decoders for “low” code block lengths N; likewise, for relatively higher code block lengths, BP decoder performance falls significantly short of ML decoder performance in some ranges of operation.

For example, for high code block lengths N of several thousands of bits (e.g., N≧10,000), the theoretical performance of conventional BP decoders substantially approaches that of optimal ML decoders in a range of operation corresponding to higher error probabilities and lower signal-to-noise ratios. However, at lower error probabilities and higher signal-to-noise ratios, BP decoder performance in this range of operation significantly degrades (the foregoing concepts are discussed further below in connection with FIG. 5A). More generally, though, LDPC codes having high block lengths in this range (e.g., N≧10,000) are computationally unwieldy to practically implement.

Presently, LDPC code block lengths on the order of a couple of thousand bits (e.g., N˜1000 to 2000) are more commonly considered for various applications. Although conventional BP decoders for this range of code block lengths do not perform as well as ML decoders, their performance approaches that of ML decoders in some cases (discussed in greater detail further below). Hence, BP decoders for this block length range are a viable decoding solution for many applications, given the significant complexity of ML decoders (which renders ML decoders useless for any practical application).

The suboptimal performance of conventional BP decoders is exacerbated compared to ML decoders, however, at code block lengths below N˜1000 and especially at relatively low code block lengths (e.g., N˜100 to 200). Low code block lengths generally are desirable at least for minimizing the overall complexity of the coding scheme, which in most cases facilitates the implementation of a fast and efficient decoder (e.g., the shorter the code, the fewer operations are needed in the decoder). Accordingly, the appreciably suboptimal performance of conventional BP decoders at relatively low code block lengths is a significant shortcoming of these decoders.

FIG. 5 graphically illustrates some comparative performance measures of a simulated conventional BP decoder and a simulated ML decoder for an LDPC block code having a relatively low code block length (the particular code used in the simulation represented in the graph of FIG. 5 is a Tanner code with N=155¹). The simulation conditions include transmission of the code over an Additive White Gaussian Noise (AWGN) channel. In the graph of FIG. 5, the horizontal axis represents the signal-to-noise ratio (SNR) for the channel in units of dB. The vertical axis represents a code word error rate (WER) on a logarithmic scale; the WER is one exemplary measure of an error probability in terms of a percentage of code words that are transmitted over the channel but not correctly recovered by the respective decoders (another common measure of error probability is a bit error rate, or BER). The lower curve 72 in FIG. 5 represents the simulated optimal ML decoder, whereas the upper curve 70 represents the simulated conventional BP decoder with one hundred iterations of a standard BP algorithm.
R. M Tanner, D. Sridhara, T. Fuja, “A class of group-structured LDPC codes,” Proceedings ICSTA 2001 (Ambleside, England), hereby incorporated herein by reference.

From the curves illustrated in FIG. 5, it may be readily appreciated that the simulated conventional BP decoder does not perform as well as the simulated ML decoder. For example, at a channel signal-to-noise ratio of 3 dB, the ML decoder has a word error rate of approximately 5×10⁻⁵, whereas the conventional BP decoder has a significantly higher word error rate of approximately 10⁻² (i.e. over two orders of magnitude worse performance for the conventional BP decoder). As would be expected, the performance of both decoders significantly degrades (i.e., the word error rate increases) as the channel signal-to-noise ratio decreases.

The simulation results shown in FIG. 5 are provided primarily for purposes of generally illustrating the comparative performance of conventional BP decoders and ML decoders at relatively low block code lengths and for error tolerances in a range commonly specified for wireless communication systems (e.g., typical error tolerances for wireless communication systems generally are specified in the range of approximately 10⁻³ to 10⁻⁴). For some other applications, however, specified error tolerances may be much lower than those indicated on the vertical axis of the graph shown in FIG. 5 (i.e., the horizontal axis of the graph of FIG. 5 would have to be extended to allow showing significantly lower word error rates on the vertical axis of the graph).

For example, in optical communications systems, presently a word error rate (WER) on the order of 10⁻⁸ or lower generally is specified as the target error tolerance for such systems. Similarly, in magnetic recording and other storage applications, presently a WER on the order of 10⁻¹¹ or lower (to about 10⁻¹⁴) generally is specified as the target error tolerance for these systems. Nonetheless, the results illustrated in FIG. 5 clearly demonstrate the generally suboptimal performance of conventional BP decoders as compared to ML decoders at relatively low block code lengths, and provide a useful indicator of the comparative performance of these decoders at error rates commonly specified for wireless communication applications, as well as significantly lower word error rates specified for other applications.

As discussed above, some current applications for LDPC codes more commonly utilize somewhat higher LDPC code block lengths on the order of a couple of thousand bits (e.g., N˜1000 to 2000). In this range of code block lengths, the performance of conventional BP decoders generally approaches that of ML decoders at lower signal-to-noise ratios (and correspondingly higher word error rates). However, at higher signal-to-noise ratios (and lower word error rates), the performance of conventional BP decoders for these code block lengths suffers from an anomaly that compromises the effectiveness of the decoders. FIG. 5A illustrates this phenomenon.

In particular, FIG. 5A depicts the performance curve 74 of a simulated conventional BP decoder for an LDPC block code having a code block length N=2640². As in the simulations of FIG. 5, the simulation conditions in FIG. 5A include transmission of the code over an AWGN channel. As illustrated in FIG. 5A, the performance curve 74 includes what is commonly referred to as a “waterfall region” 76 for lower SNR and higher WER, representing an essentially steady decrease in WER as the SNR is increased (i.e., similar to that observed in the simulations of FIG. 5). In this waterfall region, for higher code block lengths the performance of the BP decoder approaches that of an ML decoder. However, at some point in the performance curve 74 as the SNR is increased, the slope of the performance curve changes dramatically, and a further increase in SNR results in a corresponding decrease in WER at a significantly lower rate. This point of changing slope in the performance curve 74 is indicated in FIG. 5A by the reference numeral 78, and is commonly referred to as an “error floor.”
² The LDPC code used in the simulation of FIG. 5A is a (3,6) Margulis code, with block length N=2640 and a code rate R=0.5.

The phenomenon of an error floor is problematic in that it indicates a performance limitation of BP decoders for higher code block lengths: namely, at favorable signal-to-noise ratios, the decoder performs significantly worse than expected in the effort to achieve low word error rates (i.e., low error probability). For some applications in which appreciably low word error rates are specified (e.g., on the order of 10⁻¹⁴ for data storage applications), the error floor phenomenon may significantly impede the practical integration of conventional LDPC coding schemes in information transfer systems for these applications.

### SUMMARY

In view of the foregoing, the present disclosure relates generally to various modifications to conventional information coding schemes that result in an improvement in one or more performance measures for a given coding scheme.

In particular, some exemplary embodiments disclosed herein are directed to improved decoding techniques for linear block codes, such as low-density parity-check (LDPC) codes. For example, in some embodiments, techniques according to the present disclosure are applied to a conventional belief-propagation (BP) decoding algorithm to significantly improve the performance of the algorithm so as to more closely approximate that of the theoretically optimal maximum-likelihood (ML) decoding scheme.

In various implementations of such embodiments, significantly improved performance of a modified BP algorithm may be realized over a wide range of signal-to-noise ratios and for a wide range of code block lengths. For example, in various embodiments, decoder performance generally is improved for lower code block lengths, and significant error floor reduction or elimination may be achieved for higher code block lengths. These and other advantages are achieved while at the same time essentially maintaining the benefits of relative computational simplicity and execution speed of a conventional BP algorithm as compared to an ML decoding scheme.

In one aspect, methods and apparatus according to the present disclosure for improving the performance of conventional BP decoders are universally applicable to “off the shelf” LDPC encoder/decoder pairs (e.g., for either regular or irregular LDPC codes). In another aspect, the concepts underlying the various methods and apparatus disclosed herein may be more generally applied to various decoding schemes involving iterative decoding algorithms and message-passing on graphs, as well as coding schemes other than LDPC codes to similarly improve their performance. In yet other aspects, exemplary applications for various improved coding schemes according to the present disclosure include, but are not limited to, wireless (mobile) networks, satellite communication systems, optical communication systems, and data recording and storage systems (e.g., CDs, DVDs, hard drives, etc.).

By way of further example, one embodiment is directed to a decoding method for a linear block code having a parity check matrix that is sparse or capable of being sparsified. The decoding method of this embodiment comprises an act of modifying a conventional decoding algorithm for the linear block code such that a performance of the modified decoding algorithm significantly approaches or more closely approximates a performance of a maximum-likelihood decoding algorithm for the linear block code.

Another exemplary embodiment is directed to a method for decoding received information encoded using a coding scheme. The method of this embodiment comprises acts of: A) executing an iterative decoding algorithm for a predetermined first number of iterations to attempt to decode the received information; B) upon failure of the iterative decoding algorithm to provide valid decoded information after the predetermined first number of iterations, altering at least one value used by the iterative decoding algorithm; and C) executing at least a first round of additional iterations of the iterative decoding algorithm using the at least one altered value.

In one aspect of the foregoing embodiment, if the act C) does not provide valid decoded information, the method further includes acts of: F) performing one of selecting a different value for the at least one altered value and altering at least one different value used by the iterative decoding algorithm; G) executing another round of additional iterations of the iterative decoding algorithm; H) if the act G) does not provide valid decoded information, proceeding to act I; and I) repeating the acts F), G) and H) for a predetermined number of additional rounds or until valid decoded information is provided, whichever occurs first.

In another aspect of the foregoing embodiment, the method further including acts of: F) if the act C) provides valid decoded information, adding the valid decoded information to a list of valid decoded information; G) performing one selecting a different value for the at least one altered value and altering at least one different value used by the iterative decoding algorithm; H) executing another round of additional iterations of the iterative decoding algorithm; I) if the act H) provides valid decoded information, adding the valid decoded information to the list of valid decoded information; J) repeating the acts G), H) and I) for a predetermined number of additional rounds; and K) selecting from the list of valid decoded information an entry of valid decoded information that minimizes a Euclidian distance between the entry and the received information.

Yet another exemplary embodiment is directed to an apparatus for decoding received information that has been encoded using a coding scheme. The apparatus of this embodiment comprises a decoder block configured to execute an iterative decoding algorithm for a predetermined first number of iterations. The apparatus also comprises at least one controller that, upon failure of the decoder block to provide valid decoded information after the predetermined first number of iterations of the iterative decoding algorithm, is configured to alter at least one value used by the iterative decoding algorithm and control the decoder block so as to execute at least a first round of additional iterations of the iterative decoding algorithm using the at least one altered value.

It should be appreciated that all combinations of the foregoing concepts and additional concepts discussed in greater detail below are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a block-diagram of a generalized information transmission system;

FIG. 2 is a diagram of an exemplary code word format for an information coding scheme used in the information transmission system of FIG. 1;

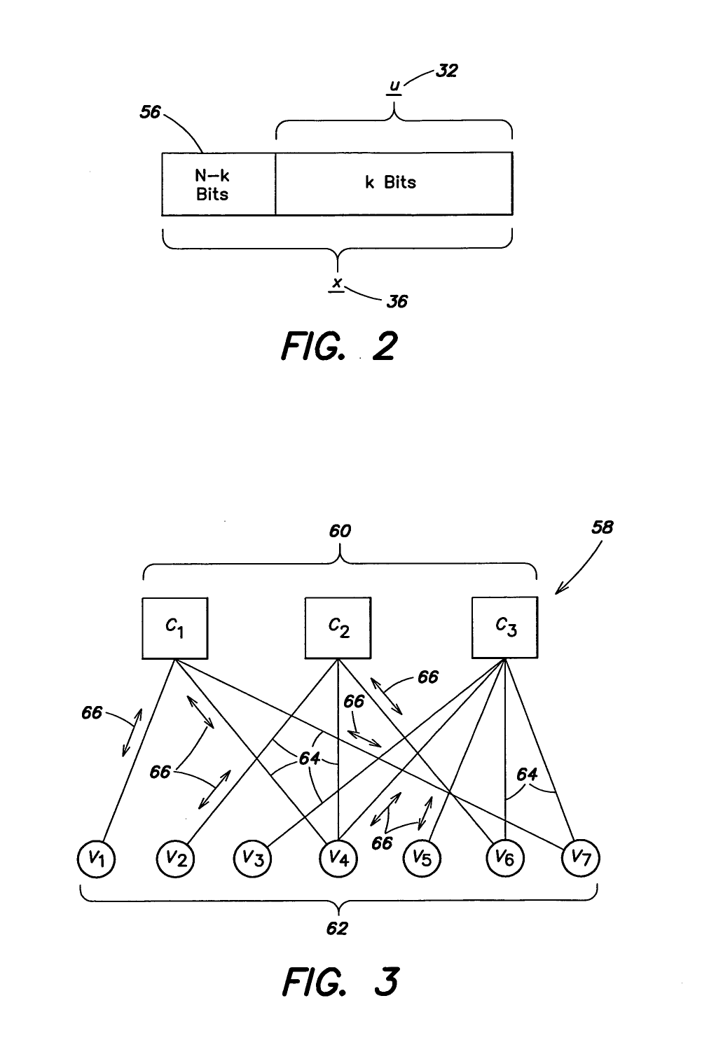

FIG. 3 is a diagram of an exemplary bipartite graph architecture used in connection with the decoding of low-density parity-check (LDPC) codes that may be employed in the information transmission system of FIG. 1;

FIG. 4 is a diagram of a generalized bipartite graph architecture for a belief-propagation (BP) decoding technique, showing additional notation for the information passed between nodes of the graph;

FIG. 5 is a graph illustrating the comparative performance of a simulated conventional maximum-likelihood (ML) decoder and a simulated conventional belief-propagation (BP) decoder for LDPC codes employed in the system of FIG. 1;

FIG. 5A is a graph illustrating the concept of error floor in connection with the performance of a conventional belief-propagation (BP) decoder for LDPC codes having higher code block lengths;

FIG. 6 is a block diagram illustrating an improved decoder according to one embodiment of the present invention;

FIG. 6A is a flow chart illustrating a general exemplary method for a modified algorithm executed by the improved decoder of FIG. 6, according to one embodiment of the invention;

FIG. 6B is a block diagram of a first example of a parity-check nodes logic portion of the decoder of FIG. 6, according to one embodiment of the invention;

FIG. 6C is a block diagram of a second example of a parity-check nodes logic portion of the decoder of FIG. 6, according to another embodiment of the invention;

FIG. 7 is a diagram illustrating a portion of the generalized bipartite graph shown in FIG. 4 corresponding to a set of unsatisfied check nodes, according to one embodiment of the invention;

FIG. 8 is a block diagram illustrating a choice of variable node(s) logic portion of the decoder of FIG. 6, according to one embodiment of the invention;

FIG. 9 is a flow chart illustrating an exemplary method executed by the choice of variable node(s) logic shown in FIG. 8, according to one embodiment of the invention;

FIG. 10 is a flow chart illustrating a modification to the method of FIG. 9, according to one embodiment of the invention;

FIG. 11 is a diagram illustrating a portion of a bipartite graph corresponding to an extended set of unsatisfied check nodes, according to one embodiment of the invention;

FIG. 12 is a flow chart illustrating an exemplary multiple-stage serial extended belief-propagation (BP) algorithm according to one embodiment of the invention;

FIG. 13 is a diagram schematically illustrating three stages of the multiple-stage algorithm of FIG. 12, according to one embodiment of the invention;

FIG. 14 is a diagram schematically illustrating three stages of a multiple-stage serial extended belief-propagation (BP) algorithm according to another embodiment of the invention;

FIG. 15 is a flow chart illustrating an exemplary multiple-stage parallel extended belief-propagation (BP) algorithm according to one embodiment of the invention;

FIG. 16 is a graph illustrating the comparative performance of a simulated conventional maximum-likelihood (ML) decoder, a simulated conventional belief-propagation (BP) decoder, an improved decoder according to one embodiment of the invention that executes the algorithm of FIG. 12, and an improved decoder according to another embodiment of the invention that executes the algorithm of FIG. 15; and

FIG. 17 is a graph illustrating the comparative performance for LDPC codes having higher code block lengths of a simulated conventional belief-propagation (BP) decoder and an improved decoder according to one embodiment of the invention.

### DETAILED DESCRIPTION

1. Overview

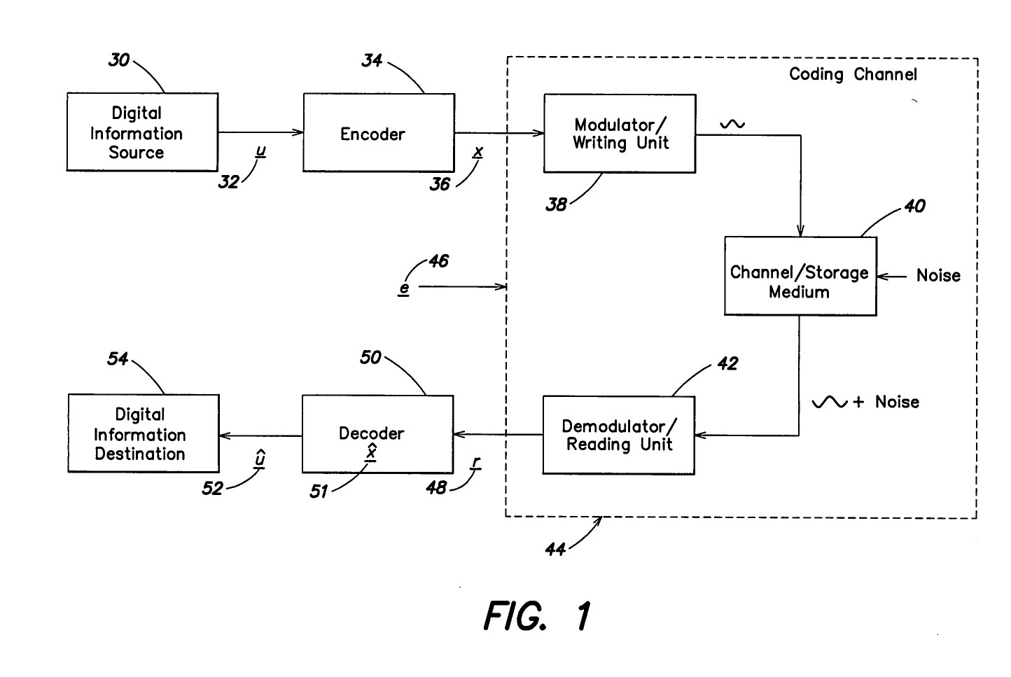

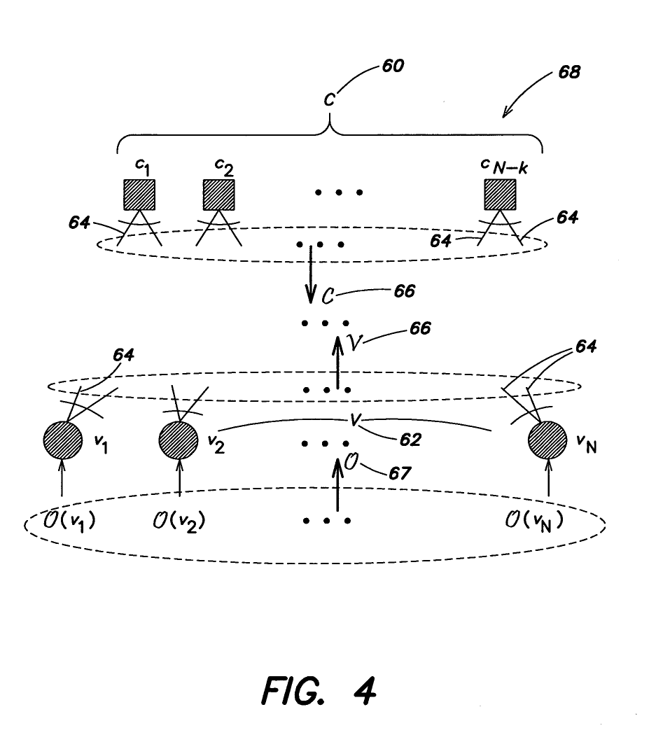

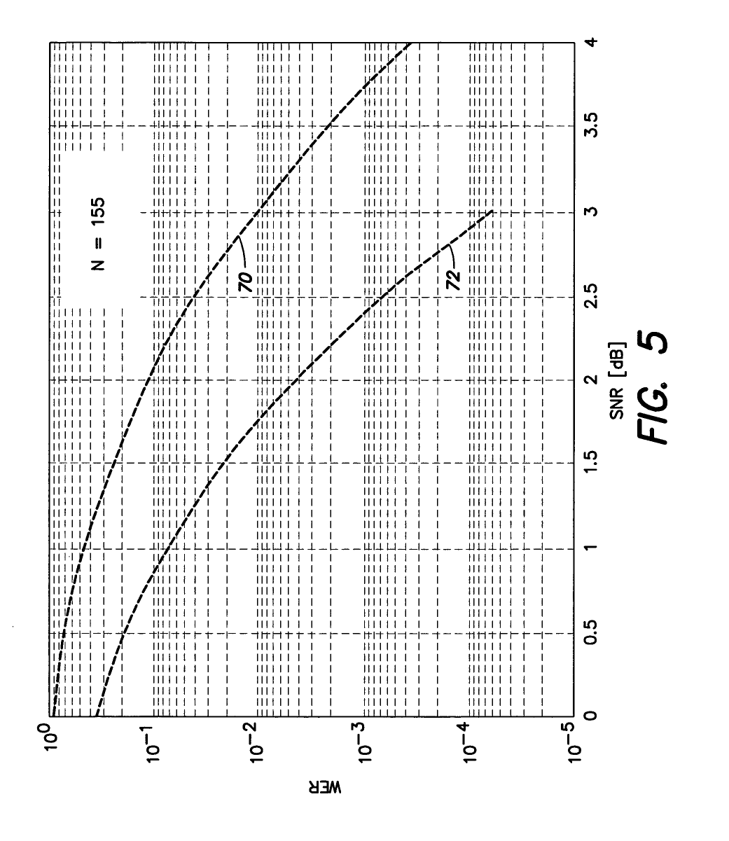

As discussed above, with reference again to the decoder 50 of the information transmission system illustrated in FIG. 1, a conventional belief-propagation (BP) decoder for a low-density parity-check (LDPC) coding scheme is configured to determine an estimated code word \hat{x} based on a received vector r obtained from a coding channel 44 of the information transmission system. Such a decoder iteratively implements a standard BP decoding algorithm based on a bipartite graph architecture (e.g., as described above in connection with FIGS. 3 and 4) dictated by the parity-check matrix H for the LDPC code.

A standard BP decoding algorithm typically is executed for some predetermined number of iterations or until the likelihoods for the logic states of the respective bits of the estimated code word \hat{x} are close to certainty, whichever occurs first. At that point in the standard BP algorithm, an estimated code word \hat{x} is calculated based on the likelihoods present at the variable nodes V of the bipartite graph (e.g., see FIG. 4, reference numeral 62). The validity of this estimated code word \hat{x} is then tested in the decoder by calculating its syndrome s; in particular, if the syndrome s equals the parity-check vector z (i.e., all zero elements), the BP decoding algorithm is said to have converged successfully to yield a valid estimated code word \hat{x}. Otherwise, if any element of the syndrome s is non-zero, the algorithm is said to have failed and yields a decoding error.

In some exemplary embodiments, methods and apparatus according to the present disclosure are configured to improve the performance of conventional BP decoders by attempting to recover a valid estimated code word \hat{x} based on a received vector r in instances where the standard BP algorithm fails (i.e., when the standard BP algorithm does not converge to yield a valid code word after a predetermined number of iterations).

For example, upon failure of the standard BP algorithm to provide a valid estimated code word, in various embodiments methods and apparatus according to the present disclosure are configured to alter or “correct” one or more likelihood values relating to the bipartite graph (i.e., messages associated with the graph), and execute additional iterations of the standard BP algorithm using the one or more altered likelihood values. In some embodiments, methods and apparatus according to the present disclosure may be configured to alter one or more likelihood values that are associated with one or more check nodes of the bipartite graph; in other embodiments, one or more likelihood values associated with one or more variable nodes of the bipartite graph may be altered. In altering a given likelihood value, methods and apparatus according to the present disclosure may be configured to alter the value by various amounts and according to various criteria; for example, in some embodiments, a given likelihood value may be altered by adjusting the value up or down by some increment, or by substituting the value with a predetermined “corrected” value (e.g., a maximum-certainty likelihood).

More specifically, in one exemplary embodiment, methods and apparatus according to the present disclosure first determine any “unsatisfied” check nodes of the bipartite graph after a predetermined number of iterations of the standard BP algorithm (the concept of an unsatisfied check node is discussed in greater detail below). Based on these one or more unsatisfied check nodes, one or more variable nodes of the bipartite graph are selected as “possibly erroneous” nodes for correction. In one aspect of this embodiment, one or more variable nodes that statistically are most likely to be in error are selected as initial candidates for correction.

According to this embodiment, these one or more “possibly erroneous” variable nodes then are “seeded” with a maximum-certainty likelihood; in particular, one or more of the channel-based likelihoods based on the received vector r (i.e., one or more of the set of messages 67 or O shown in FIG. 4) is/are altered by setting the likelihood either to a logic high state or logic low state with complete certainty. The altered likelihood is input thusly to the targeted variable node(s). With the one or more “seeded” variable nodes in place, the standard BP algorithm is executed for some predetermined number of additional iterations. Applicants have recognized and appreciated that the propagation of the seeded information throughout the bipartite graph with additional successive iterations generally facilitates the convergence of the improved algorithm, and in many cases yields a valid estimated code word \hat{x} where the standard BP algorithm produced a decoding error.

From the foregoing, it should be appreciated that methods and apparatus according to the present disclosure for improving the performance of conventional BP decoders are universally applicable to conventional LDPC coding schemes (e.g., involving either regular or irregular LDPC codes). Pursuant to the methods and apparatus disclosed herein, significantly improved performance of a modified BP algorithm may be realized over a wide range of signal-to-noise ratios and for a wide range of code block lengths. For example, in various embodiments, decoder performance generally is improved for lower code block lengths, and significant error floor reduction or elimination may be achieved for higher code block lengths. These and other advantages are achieved while at the same time essentially maintaining the benefits of relative computational simplicity and execution speed of a conventional BP algorithm as compared to an ML decoding scheme.

In general, the BP decoder of any given conventional (i.e., “off the shelf”) LDPC encoder/decoder pair may be modified according to the methods and apparatus disclosed herein such that the decoder implements an extended BP decoding algorithm to achieve improved decoding performance. It should also be appreciated that, based on modern chip manufacturing methods, the additional logic circuitry and chip space required to realize an improved decoder according to various embodiments of the present invention is practically negligible, especially when considered in light of the significant performance benefits.

Applicants also have recognized and appreciated that there is a wide range of applications for the methods and apparatus disclosed herein. For example, conventional LDPC coding schemes already have been employed in various information transmission environments such as telecommunications and storage systems. More specific examples of system environments in which LDPC encoding/decoding schemes have been adopted or are expected to be adopted include, but are not limited to, wireless (mobile) networks, satellite communication systems, optical communication systems, and data recording and storage systems (e.g., CDs, DVDs, hard drives, etc.).

In each of these information transmission environments, significantly improved decoding performance may be realized pursuant to the methods and apparatus disclosed herein. As discussed in greater detail below, such performance improvements in communications systems enable significant increases of data transmission rates or significantly lower power requirements for information carrier signals. For example, improved decoding performance enables significantly higher data rates in a given channel bandwidth for a system-specified signal-to-noise ratio; alternatively, the same data rate may be enabled in a given channel bandwidth at a significantly lower signal-to-noise ratio (i.e., lower carrier signal power requirements). For data storage applications, improved decoding performance enables significantly increased storage capacity, in that a given amount of information may be stored more densely (i.e., in a smaller area) on a storage medium and nonetheless reliably recovered (read) from the storage medium.

It should be appreciated that the concepts underlying the various methods and apparatus disclosed herein may be more generally applied to a variety of coding/decoding schemes to improve their performance. For example, improved decoding algorithms according to various embodiments of the invention may be implemented for a general class of codes that employ iterative decoding algorithms (e.g., turbo codes). In one exemplary implementation, upon failure of the decoding algorithm after some number of initial iterations, methods and apparatus according to such embodiments may be configured to alter one or more values used by the iterative decoding algorithm, and then execute additional iterations of the algorithm using the one or more altered values.

Similarly, improved decoding algorithms according to various embodiments of the invention may be implemented for a general class of “message-passing” decoders that are based on message passing on graphs. A conventional BP decoder is but one example of a message-passing decoder; more generally, other examples of message-passing decoders may essentially be approximations or variants of BP decoders, in which the messages passed along the edges of the graph are quantized. As will be readily apparent from the discussions below, several concepts disclosed herein relating to improved decoder performance using the specific example of a standard BP algorithm are more generally applicable to a broader class of “message-passing” decoders; hence, the invention is not limited to methods and apparatus based specifically on performance improvements to a standard BP algorithm/conventional BP decoder.

Furthermore, the decoding performance of virtually any linear block code employing a parity-check scheme may be improved by the methods and apparatus disclosed herein. In some embodiments, such performance improvements may be particularly significant for linear block codes having a relatively sparse parity-check matrix, or a parity-check matrix that can be effectively “sparsified.”

Following below are more detailed descriptions of various concepts related to, and embodiments of, methods and apparatus for improving performance of information coding schemes according to the present invention. It should be appreciated that various aspects of the invention as introduced above and discussed in greater detail below may be implemented in any of numerous ways, as the invention is not limited to any particular manner of implementation. Examples of specific implementations and applications are provided for illustrative purposes only.

2. Exemplary Embodiments

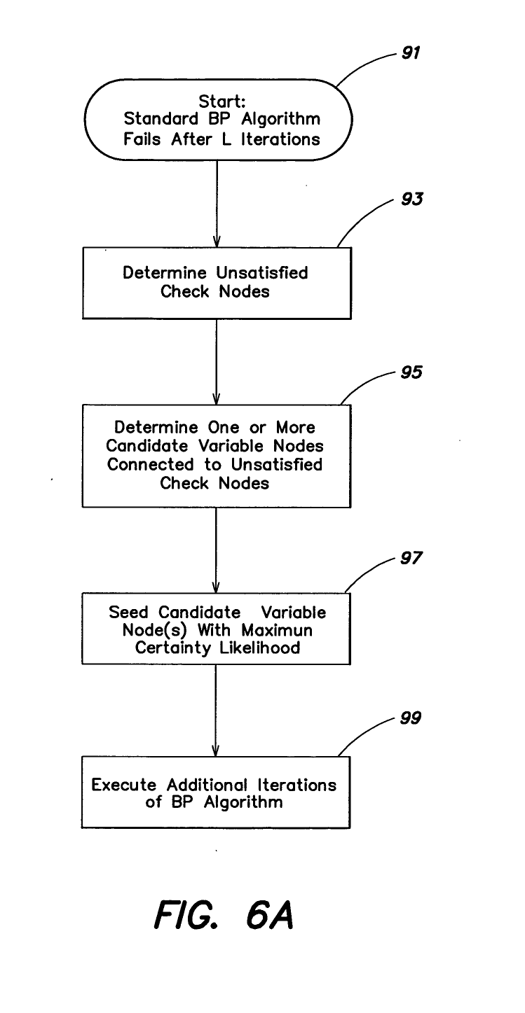

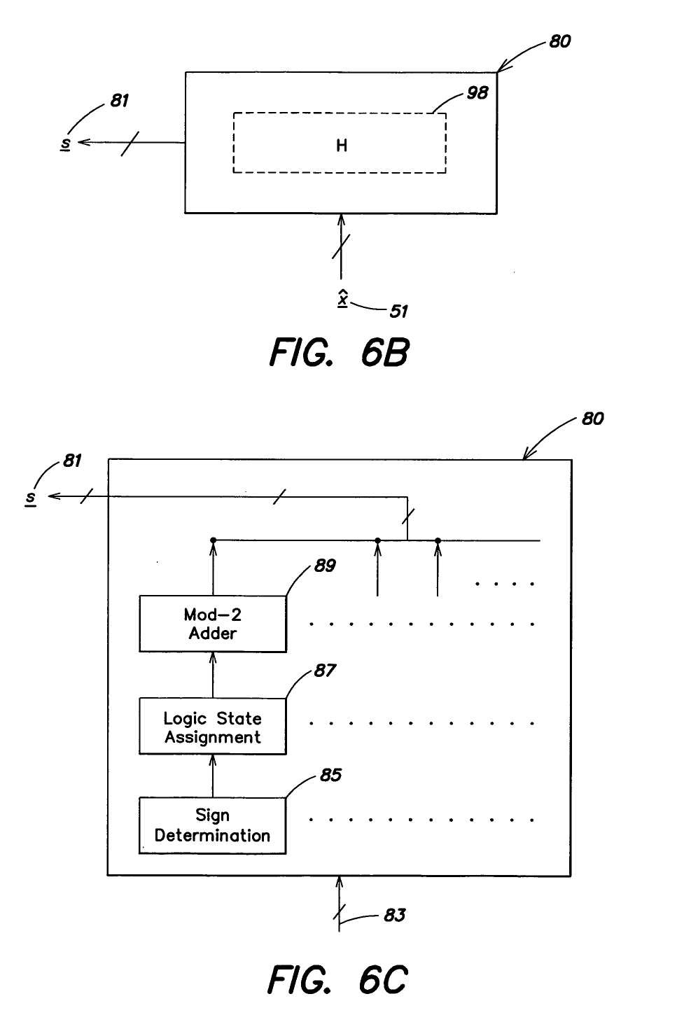

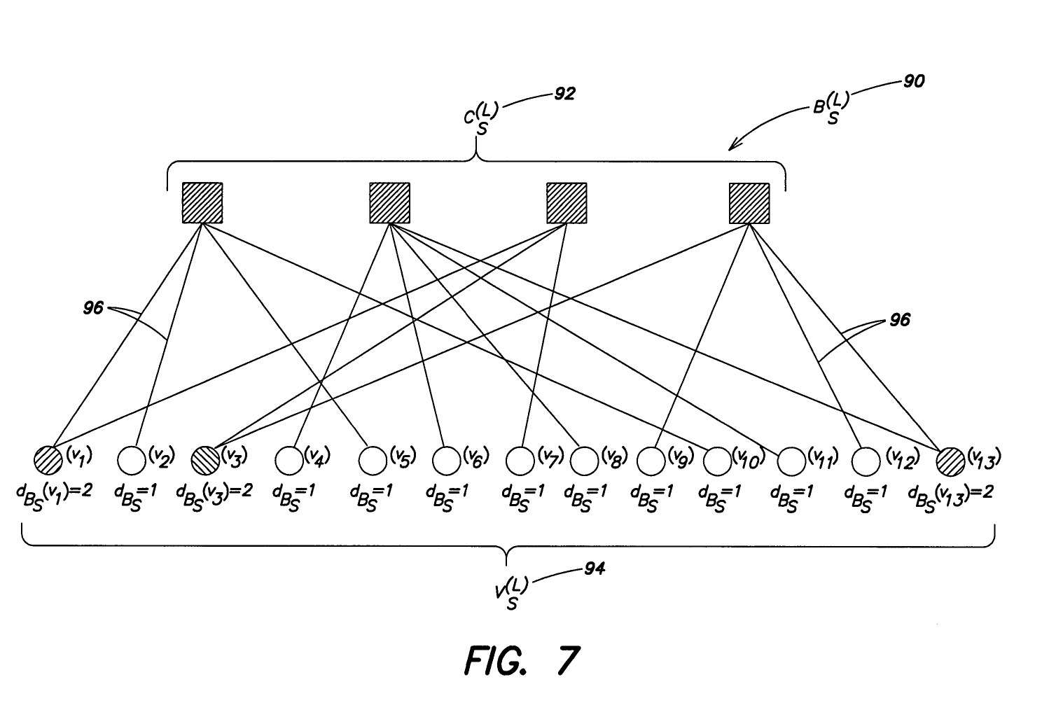

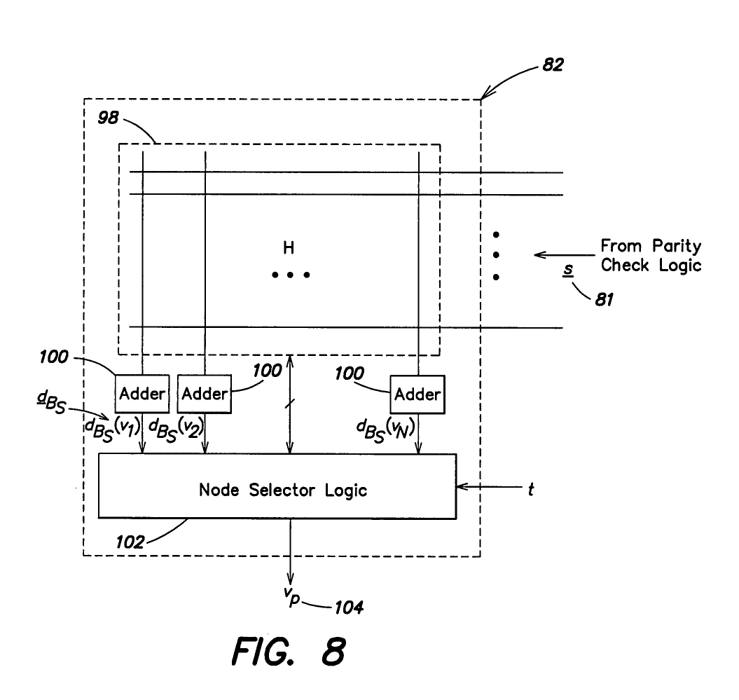

FIG. 6 is a block diagram illustrating various components of an improved decoder 500 according to one embodiment of the present disclosure. As mentioned above, for many exemplary applications, the decoder 500 shown in FIG. 6, as well as other decoders according to various embodiments of the present disclosure, may be employed in place of a portion of the conventional decoder 50 illustrated in the system of FIG. 1 that is responsible for determining an estimated code word \hat{x} (reference numeral 51 in FIGS. 1 and 6). Similarly, it should be appreciated that in some embodiments, a conventional decoder 50 may be modified according to the various concepts disclosed herein to include at least some of the functionality of the decoder 500 represented in FIG. 6, as discussed further below. In general, various realizations of the decoder 500 (or functionality associated with the decoder 500) may include an implementation as an integral component of a decoding/demodulation chip (i.e., integrated circuit) in an information transmission system receiver.

In one exemplary embodiment, the decoder 500 shown in FIG. 6 is described below as a modified belief-propagation (BP) decoder for an LDPC coding scheme. Again, the concepts underlying such an embodiment of the decoder 500 may be more generally applied to other coding schemes to similarly improve their performance.

As illustrated in FIG. 6, according to one embodiment, the decoder 500 may be configured by adding components (e.g., logic) to a portion of a conventional LDPC decoder block 50A that performs a standard BP algorithm to determine an estimated code word \hat{x}. In a conventional LDPC decoder, as in the decoder 500 of FIG. 6, generally the N elements of the received vector r (reference numeral 48) respectively are input first to a plurality of computation units 65 that calculate the channel-based likelihoods for the elements of the received vector r. As discussed above in connection with FIG. 4, the likelihoods calculated and output by the plurality of computation units 65 are denoted as a set of messages O={O(v₁), O(v₂). . . O(v_{N})} (indicated by the reference numeral 67 in FIGS. 4 and 6).

For example, given an Additive White Gaussian Noise (AWGN) coding channel with the noise standard deviation σ, the computation units 65 would be configured to calculate the respective elements of the message set O as O(vᵢ)=2rᵢ/σ², where rᵢ is a corresponding element of the received vector r (it should be appreciated that for other types of coding channels, the computation units 65 may be configured to calculate the channel-based likelihoods based on a different set of relationships). In FIG. 6, the values (likelihoods) of the message set O are applied as inputs to the LDPC decoder block 50A in a manner similar to that illustrated in FIG. 4.

In the exemplary decoder 500 shown in FIG. 6, the additional decoder components according to one embodiment of the present disclosure include parity-check nodes logic 80, choice of variable node(s) logic 82, seeding logic 84, control logic 69, and a memory unit 86. It should be appreciated that FIG. 6 schematically illustrates one exemplary arrangement and interconnection of decoder components, and that the invention is not limited to this particular arrangement and interconnection of components. In general, each of the decoder components shown in FIG. 6 and discussed herein may obtain and provide information to one or more other decoder components in a variety of manners to perform one or more functions of the decoder. According to one aspect of this embodiment, other than the control logic 69, the additional components are active in the decoder 500 only when the conventional LDPC decoder block 50A fails, i.e., when the standard BP algorithm does not converge after a predetermined number L of initial iterations to yield a valid estimated code word \hat{x}.

FIG. 6A is a flow chart illustrating a general exemplary method for a modified algorithm executed by the decoder 500 of FIG. 6, according to one embodiment of the invention. As indicated in block 91 of FIG. 6A, if after a predetermined number L of initial iterations the standard BP algorithm executed by the decoder block 50A fails, the method of FIG. 6A proceeds to block 93, in which the control logic 69 instructs the parity-check nodes logic 80 of the decoder 500 to determine any “unsatisfied” check nodes. For example, in one embodiment, one or more non-zero elements of the syndrome s=\hat{x}·H^{T} are determined after non-convergence of the standard BP algorithm, and each non-zero syndrome element represents a corresponding “unsatisfied” check node.

Based on these one or more unsatisfied check nodes, in block 95 of FIG. 6A the control logic instructs the choice of variable node(s) logic 82 to then determine one or more variable nodes of the bipartite graph as candidates for correction. In block 97, these one or more “possibly erroneous” variable nodes then are “seeded” by the seeding logic 84 with a maximum-certainty likelihood; in particular, with reference again to FIG. 6, one or more of the channel-based likelihoods 67 that normally are provided by the computation units 65 based on the received vector r (i.e., one or more elements of the set of messages O) is/are replaced by the seeding logic 84 with either a completely certain logic high state or a completely certain logic low state. These seeded values then are input to the one or more targeted variable nodes to provide revised variable node information.

With the one or more “seeded” variable nodes in place, as indicated in block 99 of FIG. 6A, the control logic 69 instructs the decoder block 50A of the decoder 500 to execute the standard BP algorithm for some predetermined number of additional iterations. In various embodiments, the counter t shown in FIG. 6 may be employed generally to keep track of various events associated with additional iterations of the algorithm, and the memory unit 86 may be employed to store various “snapshots” of information (messages) present on the bipartite graph at different points in the process, as well as identifiers for the one or more seeded variable nodes. Generally, the propagation of the seeded information throughout the bipartite graph with additional successive iterations in many cases yields a valid estimated code word \hat{x} where the standard BP algorithm originally produced a decoding error.

Following below is a more detailed discussion of the components of the decoder 500 illustrated in FIG. 6 and the method illustrated in FIG. 6A according to various embodiments of the invention.

a. Determining Unsatisfied Check Node(s) and Target Variable Node(s) for Seeding

In describing the parity-check nodes logic 80 and choice of variable node(s) logic 82 (as well as other components) of the decoder 500 shown in FIG. 6, it is useful to reference again the general bipartite graph architecture discussed above in connection with FIG. 4, and to revisit some of the terminology and notation presented in connection with this architecture.

The bipartite graph 68 of FIG. 4 for a given code may be represented by B=(V, E, C), where B denotes the overall graph structure, V denotes the set of variable nodes 62 (V 15={v₁, v₂ . . . v_{N}}), C denotes the set of check nodes 60 (C={c₁, c₂ . . . c_{N-k}}) and E denotes the set of edges 64 connecting V and C. With this notation in mind, the goal of the parity-check nodes logic 80 is to determine the “Set of Unsatisfied Check Nodes” (SUCN) after L iterations of the standard BP algorithm executed by the decoder block 50A. The set of unsatisfied check nodes SUCN after L iterations is denoted as C_{S}^{(L)}.

According to one embodiment, as illustrated in FIG. 6B, the parity-check nodes logic 80 receives as an input provided by the decoder block 50A the estimated code word \hat{x} (again, which is assumed to be invalid after L iterations of the standard BP algorithm) and employs the parity check matrix H (reference numeral 98) to evaluate the syndrome s=\hat{x}·H^{T}. This syndrome (reference numeral 81) includes at least one nonzero element. The parity-check nodes logic 80 then passes either a logic zero or logic one to the choice of variable node(s) logic 82 for each of the N-k elements of the syndrome s. Each non-zero syndrome element passed to the choice of variable node(s) logic 82 corresponds to an “unsatisfied” check node, and accordingly represents a member of the set C_{S}^{(L)}.

In another embodiment, as illustrated in FIG. 6C, the parity-check nodes logic 80 may calculate the syndrome s passed to the choice of variable node(s) logic 82 in a somewhat different manner. For example, in one embodiment, for each check node of the set C in the bipartite graph B, the parity-check nodes logic 80 may receive as an input from the decoder block 50A all of the likelihood information (i.e., messages) input to the check node from various variable nodes of the set V. Based on the aggregate likelihood information (reference numeral 83 in FIG. 6C) from all of the check nodes as received from the decoder block 50A, the parity-check nodes logic 80 may determine whether or not a given check node is satisfied or unsatisfied.

More specifically, according to the embodiment of FIG. 6C, for a given check node a sign determination block 85 of the parity-check nodes logic 80 may first examine the sign (plus or minus) of each log-likelihood message input to the check node. Based on the sign of the log-likelihood for each input to the check node as determined by the sign determination block 85, a logic state assignment block 87 may then determine whether a given input to the check node is more likely to be a logic one or a logic zero, and assign the appropriate logic state to that input. In one aspect of this embodiment, the logic state assignment block 87 may make this determination based on the conventional definitions of the messages passed between the nodes of a bipartite graph for a standard BP algorithm; namely, a log-likelihood having a positive (+) sign indicates that a logic zero is more likely than a logic one, and a log-likelihood having a negative (−) sign indicates that a logic one is more likely than a logic zero.

Once the logic state assignment block 87 has assigned a logic state for each input to a given check node, a modulo-2 adder block 89 calculates the modulo-2 (XOR) sum of the assigned logic states for the inputs to determine whether or not the check node is satisfied (this is the equivalent of the operation exemplified in equations (2) discussed above in the “Background” section). In particular, if the modulo-2 sum of the logic states assigned to the inputs is zero, the check node is satisfied and, conversely, if the modulo-2 sum is one, the check node is unsatisfied.

In the embodiment of FIG. 6C, the parity-check nodes logic 80 repeats a similar process for each check node in the set C; specifically, in one exemplary implementation, the parity-check nodes logic 80 may include a sign determination block 85, a logic state assignment block 87, and a modulo-2 adder 89 for each check node of the bipartite graph. The respective outputs of the modulo-2 adders accordingly are passed to the choice of variable node(s) logic 82 as the syndrome s. Again, each nonzero element of the syndrome s represents an unsatisfied check node.

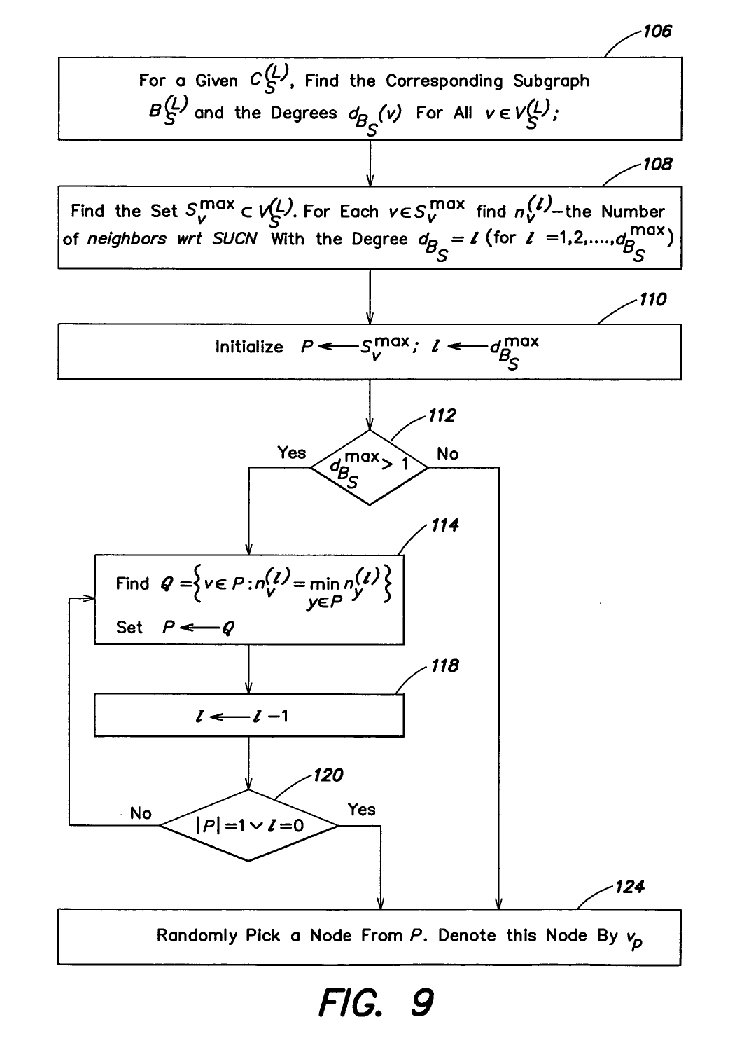

Having determined the set of unsatisfied check nodes C_{S}^{(L)}, the choice of variable node(s) logic 82 then examines all of the variable nodes connected to each unsatisfied check node by at least one edge in the graph B. With this in mind, an “SUCN code graph,” denoted as Bₛ^{(L)}=(Vₛ^{(L)}, Eₛ^{(L)}, Cₛ^{(L)}), is defined as the sub-graph of B=(V, E, C) involving only the unsatisfied check nodes Cₛ^{(L)}, all of the edges Eₛ^{(L)} emanating from the unsatisfied check nodes, and all of the variable nodes Vₛ^{(L)} connected by at least one edge in Eₛ^{(L)} to at least one unsatisfied check node Cₛ^{(L)}. FIG. 7 illustrates an example of an SUCN code graph 90. In particular, the SUCN code graph of FIG. 7 shows only the unsatisfied check nodes Cₛ^{(L)} (reference numeral 92) of a given bipartite graph and only the variable nodes Vₛ^{(L)} (reference numeral 94) connected to the unsatisfied check nodes by edges Eₛ^{(L)} (reference numeral 96).

According to various embodiments discussed further below, one of the functions of the choice of variable node(s) logic 82 is to select one or more candidate variable nodes for correction from the set Vₛ^{(L)} either randomly or according to some “intelligent” criteria (e.g., according to some prescribed algorithm, which may or may not include random elements).

To this end, in one embodiment, for each variable node in the set Vₛ^{(L)} the choice of variable node(s) logic 82 also determines how many unsatisfied check nodes the variable node is connected to. The number of unsatisfied check nodes a given variable node vᵢ is connected to in the sub-graph Bₛ^{(L)} is referred to for purposes of this disclosure as the “degree” of the variable node vᵢ, denoted as d_{B}_{_{S}}(vᵢ). It should be appreciated that, by definition, d_{B}_{_{S}}(vᵢ)=0 if vᵢ is not connected to any unsatisfied check nodes (i.e., if vᵢ is not a member of the set Vₛ^{(L)}, or vᵢ∉Vₛ^{(L)}); likewise, it should be appreciated that d_{B}_{_{S}}(vᵢ)≧1 if vᵢ is a member of the set Vₛ^{(L)} (i.e., vᵢεVₛ^{(L)}). Accordingly, in one embodiment, by identifying variable nodes of the set V with nonzero degrees, the choice of variable node(s) logic 82 implicitly determines the variable nodes in the set Vₛ^{(L)}.

The concept of “degree” also is illustrated in FIG. 7. In the example of FIG. 7, there are four unsatisfied check nodes 92 in the set Cₛ^{(L)} and thirteen variable nodes 94 in the set Vₛ^{(L)} (again, it should be appreciated that this particular example is shown to facilitate the present discussion, and that the invention is not limited to this example). For each variable node in the set Vₛ^{(L)}, the degree d_{B}_{_{S}} (vᵢ) is indicated in FIG. 7, based on the number of edges 96 connecting the particular variable node to one or more unsatisfied check nodes. More generally, the degree of any node in a given bipartite graph (either a variable node or a check node) may be determined by the number of edges emanating from the node (in this respect, the degree of each check node cᵢ in the set Cₛ^{(L)} may be similarly denoted as d_{B}_{_{S}}(cᵢ), cᵢεCₛ^{(L)}).

Applicants have recognized and appreciated that, in general, the higher the degree of a given variable node in the set Vₛ^{(L)}, the more likely the variable node is in error. Stated differently, if a first variable node is associated with a relatively higher number of unsatisfied check nodes, and a second variable node is associated with a relatively lower number of unsatisfied check nodes, it is more likely that the first variable node is in error.

Applicants have verified this phenomenon via statistics obtained by simulations of a large number of blocks for different codes. For example, in a given simulation, a large number of blocks of a particular code³ were transmitted over a noisy channel and processed using a standard BP decoding algorithm executing some predetermined number L of iterations. For each block processed that resulted in a decoding error, the erroneous bit(s) of the decoded word were identified, and the bipartite graph of the BP algorithm was examined to identify the corresponding variable node(s) contributing to the decoding error. It was observed generally from such simulations that higher-degree variable nodes were in error with noticeably greater probability than lower-degree nodes.
³ The codes simulated include the Tanner (155,64) code referenced in footnote 1, as well as regular (3,6) Gallager codes discussed in “Near Shannon limit performance of low-density parity-check codes,” D. J. C. MacKay and R. M. Neal, Electronic Letters, Vol. 32, pp. 1645-1646, 1996, hereby incorporated herein by reference.

In view of the foregoing, in one embodiment, another task of the choice of variable node(s) logic 82 is to identify those one or more variable nodes in the set Vₛ^{(L)} with the highest degree, as these one or more nodes are the most likely candidates for some type of correction or “seeding.”

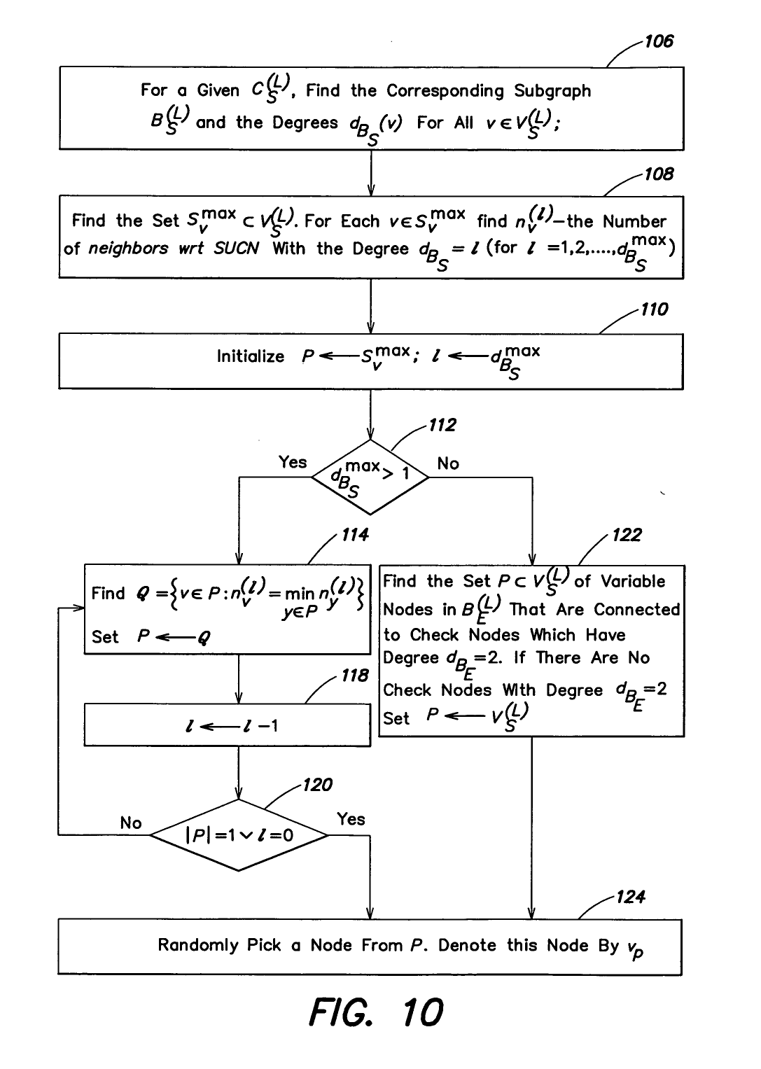

Accordingly, in one embodiment as illustrated in FIG. 8, the choice of variable node(s) logic 82 employs the parity-check matrix H (reference numeral 98) and a plurality of adders 100 to facilitate a determination of the respective degrees of every variable node in the entire set V for the code graph B, based on the syndrome s. Again, if the degree of a given variable node vᵢ is zero, then by definition this variable node is not in the set Vₛ^{(L)}. The determination of the respective degrees of every variable node in the entire set V may be viewed in terms of the function d_{B}_{_{S}}=s·H, where d_{B}_{_{S}} is a vector having N elements whose values respectively are the degrees of the N variable nodes of the entire bipartite graph B (i.e., d_{B}_{_{S}}=[d_{B}_{_{S}}(v₁), d_{B}_{_{S}}(v₂) . . . d_{B}_{_{S}}(v_{N})], as indicated in FIG. 8). This function may be realized, as shown in FIG. 8, by adding up the respective nonzero elements of each column of the parity-check matrix H after each of the N-k rows of the parity-check matrix H is multiplied by a corresponding bit of the syndrome s. Since every nonzero element of the parity-check matrix H represents one of the edges E of the complete bipartite graph B, and since every nonzero element of the syndrome s represents an unsatisfied check node, this operation essentially calculates the number of edges in the set E_{S}^{(L)} that are connected to each variable node in the set Vₛ^{(L)}.

Once the vector d_{B}_{_{S}} is determined, node selector logic 102 of the choice of variable node(s) logic 82 shown in FIG. 8 examines all of the nonzero elements of this vector (again, which represent the respective degrees of all of the variable nodes in the set Vₛ^{(L)}) and identifies the one or more variable nodes with the highest degree. For example, with reference again to the exemplary sub-graph Bₛ^{(L)} (reference numeral 90) shown in FIG. 7, the node selector logic 102 would identify the variable nodes v₁, V₃ and v₁₃ (shaded circles) each as having the highest degree (d_{B}_{_{S}}(vᵢ)=2) amongst all of the variable nodes examined (it should be readily apparent from this example that more than one variable node in the set Vₛ^{(L)} may have the same highest degree). The notation

$${d}_{{B}_{S}}^{max} = {max}_{v ∈ {V}_{S}^{( L )}} {d}_{{B}_{S} ( v )}$$

is used to denote the value of this highest degree, and the notation
Sᵥ^{max}={vεV_{S}^{(L)}:d_{B}_{_{S}}(v)=d_{B}_{_{S}}^{max}}
is used to denote the set of all variable nodes in V_{S}^{(L)} having this highest degree. Accordingly, in the example shown in FIG. 7, Sᵥ^{max}={v₁, v₃, v₁₃}.

If the node selector logic 102 of FIG. 8 has identified only one variable node in the set Sᵥ^{max}, the choice of variable node(s) logic 82 selects this node as a candidate for correction and provides an identifier for this node as an output, denoted as vₚ (reference numeral 104), to the seeding logic 84 shown in FIG. 6. As discussed further below in Section 2b, the seeding logic is configured to then “seed” this variable node vₚ with a maximum-certainty channel-based likelihood O(vₚ) (i.e., the corresponding one of the channel-based likelihoods 67 is replaced in the appropriate computation unit of the units 65 with either a completely certain logic high state or a completely certain logic low state).

If however the node selector logic 102 identifies multiple variable nodes in the set Sᵥ^{max}, a number of different options are possible according to various embodiments. For example, in one embodiment, the node selector logic 102 may randomly pick one of the nodes in the set Sᵥ^{max} to pass onto the seeding logic 84 as the node vₚ for seeding. In another embodiment, the node selector logic 102 may randomly pick two or more of the nodes in the set Sᵥ^{max} to pass onto the seeding logic for simultaneous seeding.

In other embodiments, the node selector logic 102 may “intelligently” pick (i.e., according to some prescribed algorithm) one or more nodes in the set Sᵥ^{max} to pass onto the seeding logic for seeding. In such embodiments involving “intelligent” selection, it should be appreciated that a variety of criteria may be employed by the node selector logic 102 to pick one or more nodes for seeding, and that the invention is not limited to any particular criteria. Rather, the salient concept according to this embodiment is that one or more variable nodes in the set Sᵥ^{max} are the most likely to be in error due to their high degree, and hence are the best candidates for seeding, whether chosen randomly or intelligently.

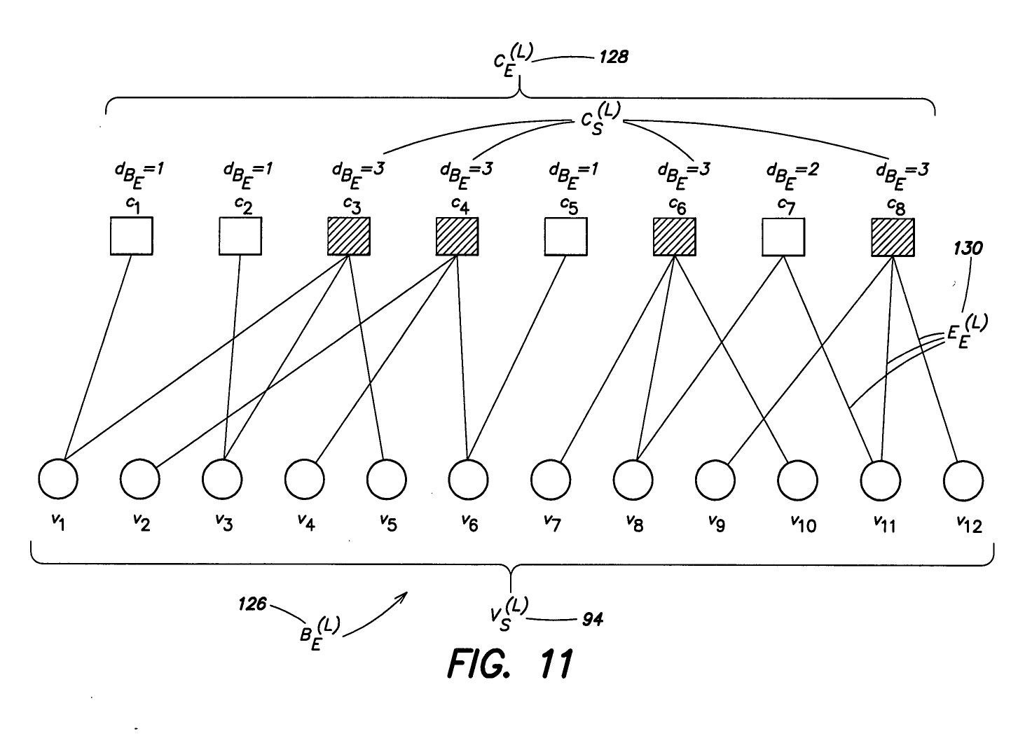

FIG. 9 is a flow chart illustrating one exemplary method executed by the choice of variable node(s) logic 82 shown in FIG. 8 for selecting a single variable node vₚ for seeding, according to one embodiment of the present disclosure. In the method shown in FIG. 9, the variable node(s) logic 82, and more particularly the node selector logic 102 of FIG. 8, incorporates both intelligent and random approaches to selecting a single node VP for seeding.

In general, if the method of FIG. 9 identifies that there is only one variable node in the set Sᵥ^{max}, it selects this node as the node vₚ for seeding as discussed above. If on the other hand the set Sᵥ^{max} includes multiple nodes, according to one embodiment the method of FIG. 9 endeavors to identify one node of the multiple nodes in the set S^{max} that, by some criterion, is the most likely to be in error. In certain circumstances, the method may randomly select one node from the set Sᵥ^{max}. In any case, the method of FIG. 9 provides one candidate variable node as the node vₚ for seeding. Again, it should be appreciated that the method described in greater detail below in connection with FIG. 9 is provided primarily for purposes of illustrating one exemplary embodiment, and that the invention is not limited to this example.

As discussed above, the method outlined in FIG. 9 is performed only if a standard BP algorithm fails to provide a valid estimated code word \hat{x} after some predetermined number L of iterations. At this point, as indicated in block 106 of FIG. 9 and as discussed above (e.g., in connection with FIGS. 6A and 6B), first the sub-graph B_{S}^{(L)}=(V_{S}^{(L)}, E_{S}^{(L)}, C_{S}^{(L)}) is determined based on the nonzero elements of the syndrome s (which represent the set of unsatisfied check nodes C_{S}^{(L)}). Based on the sub-graph B_{S}^{(L)}the degrees of all of the variable nodes V_{S}^{(L)} are determined (e.g., as discussed in connection with FIGS. 7 and 8).

In block 108 of FIG. 9, next the set of highest degree variable nodes Sᵥ^{max} is determined (again, with reference to the example shown in FIG. 7, these are the variable nodes depicted as shaded circles). In general, for multiple variable nodes in the set Sᵥ^{max}, the method of FIG. 9 endeavors to identify one node in the set Sᵥ^{max} that, by some criterion, is the most likely to be in error. According to one embodiment, this selection criterion is based on the number and degree of “neighbors” of each node in the set Sᵥ^{max}.

For purposes of the present disclosure, two variable nodes in the set V_{S}^{(L)} are defined as “neighbors” if they are both connected to at least one common unsatisfied check node in C_{S}^{(L)}. For example, with reference again to FIG. 7, the variable node v, in the set Sᵥ^{max} is a neighbor of v₂, v₅, and v₁₀ (via the left-most unsatisfied check node), as well as v₃ and v₇ (via the unsatisfied check node that is third from the left).

As mentioned above, for each variable node in the set Sᵥ^{max}(vεSᵥ^{max}), the method of FIG. 9, as indicated in block 108, identifies any neighbors of the node, the degree of each neighbor, and the number of neighbors with the same degree. In particular, the number of neighbors of a node vᵢ with the same degree d_{B}_{_{S}}=l (for l=1, 2 . . . d_{B}_{_{S}}^{max}) is denoted as nᵥ_{ᵢ}^{(l)}. Again with reference to the example of FIG. 7, for the node v₁ it can be seen that nᵥ_{ᵢ}^{(l)}=4 (there are four neighbors with degree one), and nᵥ_{₂}⁽²⁾=1 (there is one neighbor with degree two). Similarly, for the node V₃, it can be seen that nᵥ_{₃}⁽¹⁾=3 (there are three neighbors with degree one), and nᵥ_{₃}⁽²⁾=2 (there are two neighbors with degree two). Finally, for the node v₁₃ it can be seen that

$${n}_{{v}_{13}}^{( 1 )} = 6$$

(there are six neighbors with degree one) and

$${n}_{{v}_{13}}^{( 2 )} = 1$$

(there is one neighbor with degree two).

Applicants have recognized and appreciated that for multiple variable nodes in the set Sᵥ^{max}, a given variable node is incorrect with higher probability if it has a smaller number of high-degree neighbors. Stated differently, if a given node in Sᵥ^{max} has a relatively larger number of high-degree neighbors as compared to one or more other nodes in Sᵥ^{max}, it is possible that some of the high-degree neighbors of the given node could be contributing to decoding errors, as these other high-degree neighbors by definition have some influence on multiple unsatisfied check nodes. However, if a given node in Sᵥ^{mxx} has a relatively smaller number of high-degree neighbors as compared to one or more other nodes in Sᵥ^{max}, it is more likely that this given node is in error, as its neighbors arguably contribute less to potential decoding errors because they have an influence on fewer unsatisfied check nodes.

In view of the foregoing, for multiple variable nodes in the set Sᵥ^{max}, the method of FIG. 9 endeavors to identify one node in the set Sᵥ^{max} that is the most likely to be in error based on the number and degree of its neighbors. More specifically, according to one aspect of this embodiment, the method of FIG. 9 first attempts to identify the highest degree for which either only one node in the set Sᵥ^{max} has the minimum number of neighbors of that degree, or two nodes of the set Sᵥ^{max} have the same minimum number of neighbors of that degree. If at this degree only one such node is identified, it is selected as the node vₚ for seeding. If on the other hand two such nodes are identified, the method then looks at the number of neighbors for each of these two nodes at successively lower degrees and endeavors to select the one node of the two nodes with the fewer number of neighbors at the next lowest degree at which the two nodes have different numbers of neighbors.

The foregoing points are generally illustrated using some exemplary scenarios represented by Tables 1, 2 and 3 below. For instance, in the example of Table 1, the set Sᵥ^{max} is found in block 108 of FIG. 9 to contain three nodes, v₁, v₂ and v₃, each having the highest degree d_{B}_{_{S}}^{max}=4. For each node v₁, v₂ and v₃, the rows of Table 1 list the number of neighbors having a particular degree l, or nᵥ_{₁}^{(l)}, as determined in block 108.

TABLE 1

| | ν₁ ∈ S_{ν}^{max} | ν₂ ∈ S_{ν}^{max} | ν₃ ∈ S_{ν}^{max} |
|---|---|---|---|
| n_{ν}_{ᵢ}⁽⁴⁾ | 2 | 2 | 2 |
| n_{ν}_{ᵢ}⁽³⁾ | 5 | 2 | 3 |
| n_{ν}_{ᵢ}⁽²⁾ | 4 | 6 | 4 |
| n_{ν}_{ᵢ}⁽¹⁾ | 20 | 25 | 30 |

In the example of Table 1, each of the three nodes has two neighbors having degree-four. However, with respect to degree-three, one node (v₁) has five degree-three neighbors, one node (v₂) has two degree-three neighbors, and one node (v₃) has three degree-three neighbors. In this example, according to one embodiment, the remaining blocks in the method of FIG. 9 would select the node v₂ as the node vₚ for seeding, as it is the single node having the minimum number of highest degree neighbors (as indicated in bold in Table 2).

Table 2 below offers another example for generally illustrating the method of FIG. 9. Table 2 differs from Table 1 only in that the number of degree-three neighbors for the node v₂ is changed from two to three.

TABLE 2

| | ν₁ ∈ S_{ν}^{max} | ν₂ ∈ S_{ν}^{max} | ν₃ ∈ S_{ν}^{max} |
|---|---|---|---|
| n_{ν}_{ᵢ}⁽⁴⁾ | 2 | 2 | 2 |
| n_{ν}_{ᵢ}⁽³⁾ | 5 | 3 | 3 |
| n_{ν}_{ᵢ}⁽²⁾ | 4 | 6 | 4 |
| n_{ν}_{ᵢ}⁽¹⁾ | 20 | 25 | 30 |

In particular, Table 2 shows that each of the three nodes again has two neighbors having degree-four. However, with respect to degree-three, one node (v₁) has five degree-three neighbors and the other two of the three nodes (i.e., v₂ and v₃) have three degree-three neighbors each. Accordingly, in this example, the method of FIG. 9 would note that degree-three is the highest degree for which only two nodes of the set Sᵥ^{max} have the same minimum number of neighbors, and would identify only the nodes v₂ and V₃ for further consideration (i.e., the method would no longer consider the node v₁ as a candidate for seeding).

Having isolated only two nodes v₂ and v₃ in the example of Table 2, the method of FIG. 9 then would look at the number of neighbors for each of these two nodes at successively lower degrees (i.e., starting with degree-two). At the next lowest degree at which the two nodes v₂ and v₃ have different numbers of neighbors, the method selects the node with the fewer number of neighbors. In the example of Table 2, the next lowest degree at which the two nodes have different numbers of neighbors is degree-two, and the node with the fewer number of neighbors at degree-two is the node v₃ (i.e., v₂ has six degree-two neighbors and v₃ has four degree-two neighbors, as indicated in bold in Table 2). Hence, in the example of Table 2, node v₃ is selected as the node vₚ for seeding.

The foregoing concepts may be reinforced with reference to a third example given in Table 3 below, which represents the scenario of the sub-graph 90 shown in FIG. 7.

TABLE 3

| | ν₁ ∈ S_{ν}^{max} | ν₃ ∈ S_{ν}^{max} | ν₁₃ ∈ S_{ν}^{max} |
|---|---|---|---|
| n_{ν}_{ᵢ}⁽²⁾ | 1 | 2 | 1 |
| n_{ν}_{ᵢ}⁽¹⁾ | 4 | 3 | 6 |

In the example shown above in connection with FIG. 7 as indicated in Table 3, the method of FIG. 9 would determine that degree-two is the highest degree for which only two nodes of the set Sᵥ^{max} have the same minimum number of neighbors; thus, the method would identify only the nodes v₁ and v₁₃ for further consideration and would no longer consider the node v₃ as a candidate for seeding.

Having isolated the two nodes v₁ and v₁₃ in the example of Table 3, the method of FIG. 9 then would look at the number of neighbors for each of these two nodes at degree-one, at which degree the method selects the node with the fewer number of neighbors. In the example of Table 3, the node with the fewer number of neighbors at degree-one is the node v₁ (i.e., v₁ has four degree-one neighbors, as indicated in bold in Table 3, whereas v₁₃ has six degree-one neighbors). Hence, in the example of Table 3, node v₁ is selected as the node vₚ for seeding.

Following is a more detailed explanation of the remaining blocks of the method of FIG. 9 for selecting the node vₚ according to the principles underlying the examples given immediately above.

In block 110, the method of FIG. 9 initializes a node set P to duplicate the set Sᵥ^{max} and also initializes a counter l to the highest degree d_{B}_{_{S}}^{max}. In block 112, the method of FIG. 9 asks if the highest degree d_{B}_{_{S}}^{max} is greater than one. If the answer to this question is no (i.e., if the highest degree is one), the method of FIG. 9 considers that all of the nodes in Sₓ^{max} are equally likely to be in error. Hence, the method proceeds directly to block 124, at which point one of the nodes in Sᵥ^{max} is picked randomly as the node vₚ for seeding.

If on the other hand the highest degree is determined to be greater than one in block 112 of FIG. 9, the method proceeds to block 114. In block 114, the method determines the set Q of one or more nodes from the set P having the minimum number of neighbors with degree l (recall that initially l is set to d_{B}^{max}). If all nodes in P have the same number of neighbors with degree l, then the contents of the set Q is identical to that of the set P. In any case, block 144 ultimately redefines the set P with the contents of the set Q (which may be the same or less than the former contents of the set P).

In block 118, the degree l is decremented (l←l−1) before proceeding to block 120. In block 120, the method of FIG. 9 asks if the number of nodes in the redefined set P is equal to one or if the degree l has been decremented to zero. If either of these conditions is true, the method proceeds to block 124. If upon proceeding to block 124 there is only one node remaining in the redefined set P, this node is selected as the node vₚ for seeding. If on the other hand the method has entered block 124 with more than one node in the redefined set P and the degree l decremented to zero, it implies that there are multiple nodes having the same minimum number of neighbors with degree-one. In this situation, as indicated in block 124, the method of FIG. 9 randomly picks one of the nodes in the redefined set P as the node vₚ for seeding.

If however in block 120 the method of FIG. 9 determines that there is more than one node in the set P and the degree l is not yet decremented to zero, the method returns to block 114 where the set Q is redefined based on the current set P and the decremented degree l from block 118.

Once returned to the block 114 from the block 120, as mentioned above the method redefines the set Q as the one or more nodes having the minimum number of neighbors at the decremented degree l, and then updates the set P to reflect the contents of this set Q. The method then continues through the subsequent blocks as discussed above until the node vₚ is determined.

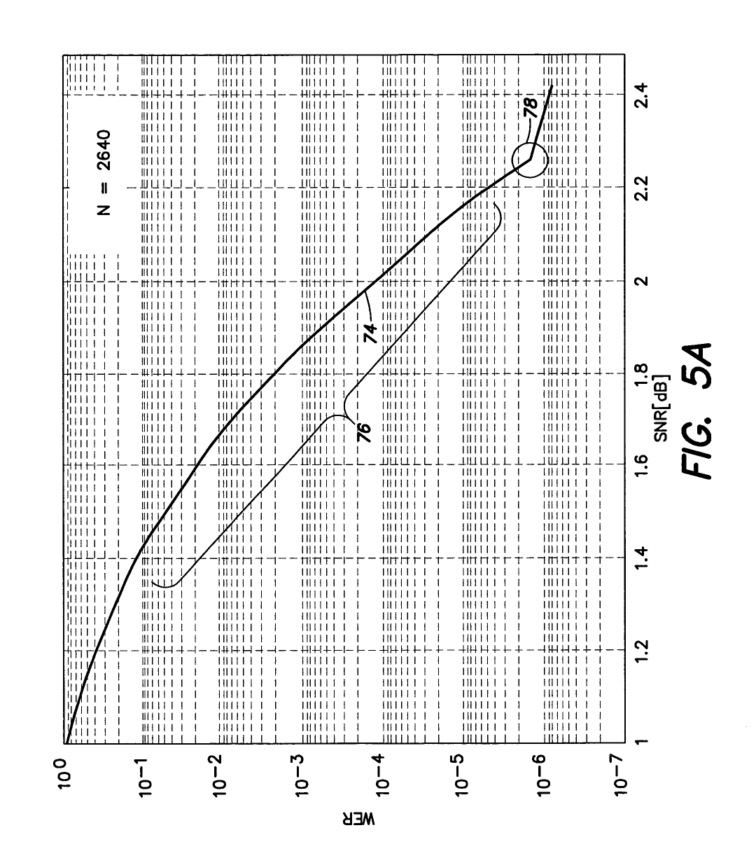

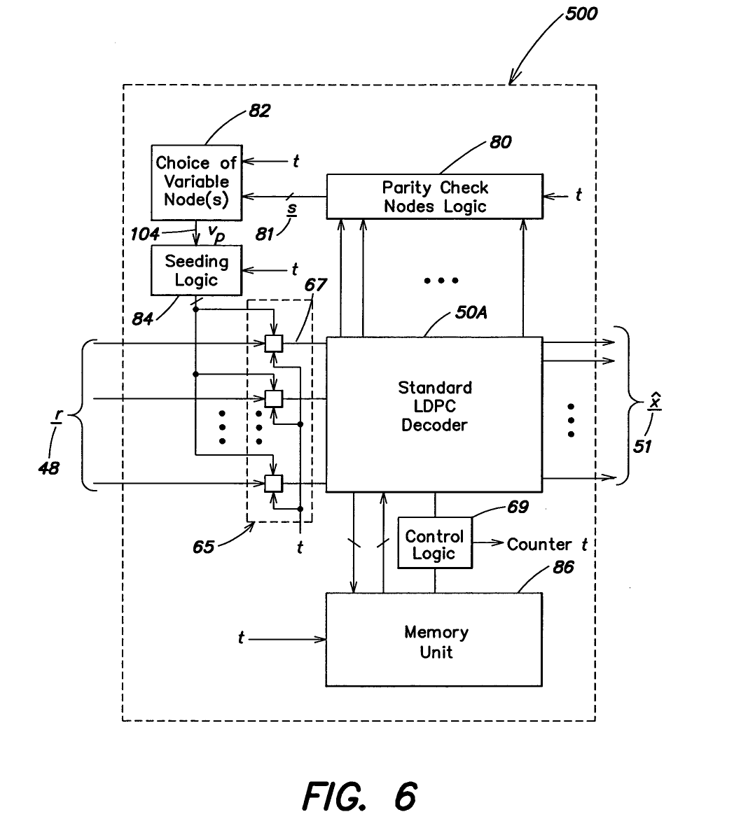

As discussed further below in Section 3, by effectively selecting for correction a variable node vₚ that is statistically most likely to be in error, the method of FIG. 9 facilitates significantly improved performance of a modified BP algorithm according to various embodiments disclosed herein. This performance improvement is especially noteworthy for low code block lengths (e.g., N˜100 to 200—see FIG. 5). For codes with longer code block lengths (e.g., N˜1000 to 2000—see FIG. 5A), performance improvement due at least in part to the method of FIG. 9 also can be observed in the “waterfall” region, although perhaps more so in the “error floor” region (i.e., reduced error floor).

In yet another embodiment, the method of FIG. 9 may be slightly modified to further improve performance particularly in the error floor region. With reference again to the graphs of FIGS. 5 and 5A, it is readily observed that at higher signal-to-noise ratios (SNR), the standard BP algorithm executed by a conventional decoder results in lower word error rates (WER). Applicants have observed that, generally speaking, when the standard BP algorithm fails in the higher SNR/lower WER region, the resulting SUCN code graph B_{S}^{(L)} contains a significant number of variable nodes vᵢεV_{S}^{(L)} with degree-one, i.e., d_{B}_{_{S}}(vᵢ)=1. More specifically, it has been observed especially for higher code block lengths in the error floor region that when the standard BP algorithm fails, in some cases all of the variable nodes in the set V_{S}^{(L)} have degree-one (i.e., Sᵥ^{max}=V_{S}^{(L)}; d_{B}_{_{S=}}1).

In connection with block 112 of FIG. 9, in the situation described immediately above (i.e., d_{B}_{ₘₐₓ}=1) the method of FIG. 9 bypasses several algorithm elements (e.g., blocks 114, 118 and 120) and merely randomly picks one of the variable nodes in the set V_{S}^{(L)} as the candidate node vₚ for correction, as indicated in block 124. As mentioned above, this approach has resulted in some noticeable performance improvement. However, Applicants have recognized and appreciated that a modification to the method of FIG. 9 in this situation may dramatically improve performance at higher signal-to-noise ratios, and especially in the error floor region, by attempting to make a somewhat more “intelligent” selection (rather than a completely random selection) of the candidate node vₚ.

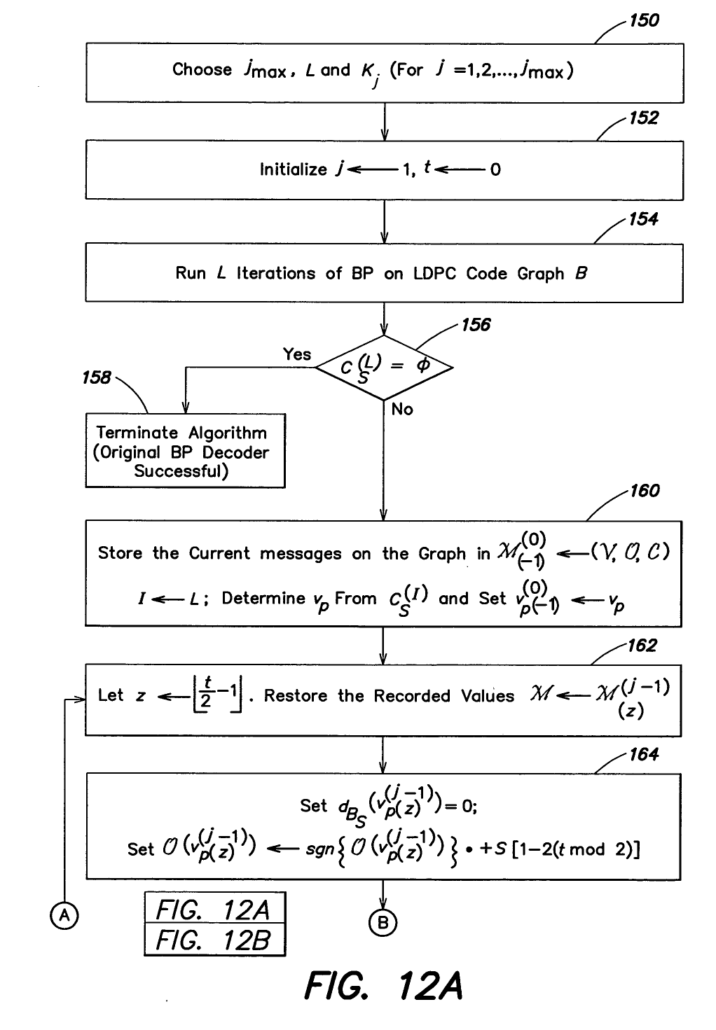

To this end, FIG. 10 illustrates a flow chart including a modification to the method of FIG. 9, according to one embodiment of the invention. FIG. 10 is identical to FIG. 9 except for block 122 in the lower right hand side of the flow chart. In particular, in FIG. 10, if the method determines in block 112 that the maximum degree d_{B}_{_{S}}^{max} of all of the nodes in Sᵥ^{max} is one, the method does not necessarily pick one of the nodes randomly as the node vₚ (as indicated in block 124). Rather, in block 122, the method first examines an “Extended Set of Unsatisfied Check Nodes” (ESUCN) relating to the variable nodes in the set V_{S}^{(L)} in an effort to make a reasoned selection for the node vₚ.

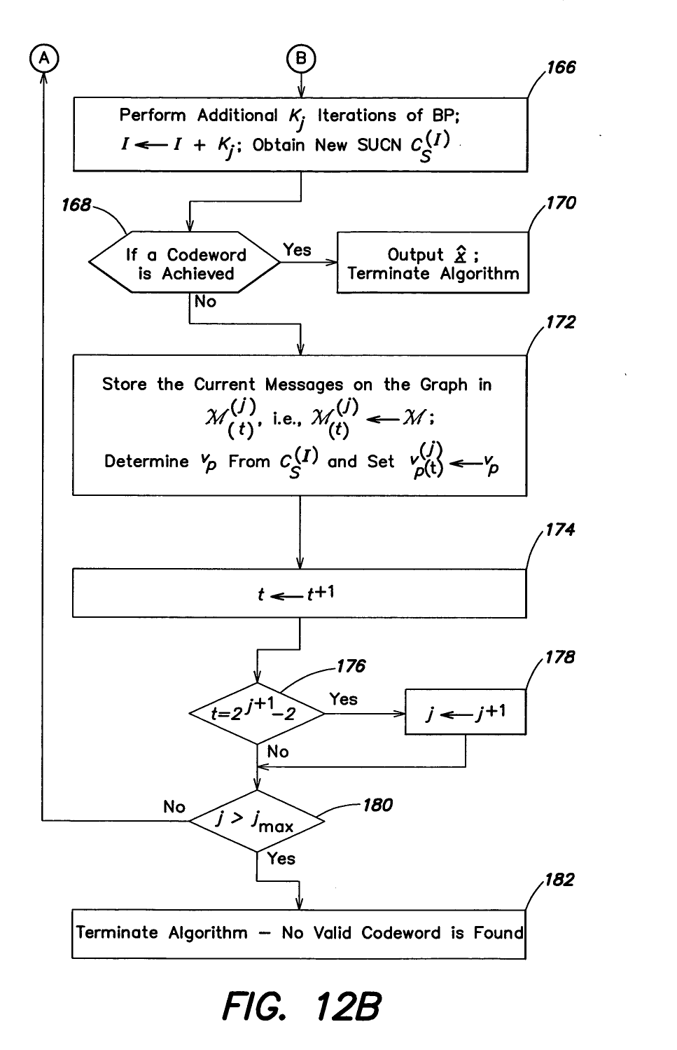

With respect to block 122 of FIG. 10, an ESUCN is defined as the set of both satisfied and unsatisfied check nodes connected (by at least one edge) to at least one variable node in V_{S}^{(L)}. FIG. 11 illustrates an example 126 of an “ESUCN code graph,” denoted as B_{S}^{(L)}=(V_{S}^{(L)}, E_{S}^{(L)}, C_{S}^{(L)}, and defined as the sub-graph of B=(V, E, C) involving the variable nodes V_{S}^{(L)} (reference numeral 94), all of the edges E_{S}^{(L)} (reference numeral 130) emanating from the variable nodes V_{S}^{(L)}, and all of the check nodes C_{E}^{(L)} (reference numeral 128), both satisfied and unsatisfied, that are connected by at least one edge in E_{E}^{(L)} to at least one variable node in the set V_{S}^{(L)}. In the example of FIG. 11, there are twelve variable nodes (v₁-v₁₂) and eight check nodes (c₁-c₈), wherein the check nodes c₃, c₄, c₆ and c₈ are unsatisfied (the unsatisfied check nodes C_{S}^{(L)} are illustrated as blackened squares and form a subset of the extended set C_{E}^{(L)}).

In FIG. 11, it should be readily verified that all of the variable nodes in the set V_{S}^{(L)} are degree-one with respect to the set of unsatisfied check nodes C_{S}^{(L)}. Accordingly, if the example of FIG. 11 were being evaluated by the method of FIG. 10, the method would determine in block 112 that all variable nodes in Sᵥ^{max} are degree-one (i.e., Sᵥ^{max}=V_{S}^{(L)}; d_{B}_{_{S}}^{max}=1), and the method would proceed to block 122.

As indicated in block 122, the method of FIG. 10 determines the ESUCN code graph B_{E}^{(L)} based on the previously determined variable node set V_{S}^{(L)}, and evaluates the respective degrees of all of the check nodes cᵢ in the extended check node set C_{E}^{(L)} (e.g., in one embodiment, this may be accomplished in an analogous manner to that discussed above in connection with FIG. 8). In the exemplary code graph of FIG. 11, these check node degrees d_{B}_{_{E}} (cᵢ) are indicated above the check nodes. According to this embodiment, the method of FIG. 10 then particularly looks for one or more degree-two check nodes in the set C_{S}^{(L)} (i.e., d_{B}_{_{E}}(cᵢ)=2) (in the example of FIG. 11, the only degree-two check node is c₇).

In the method of FIG. 10, if there are no degree-two check nodes found in block 122, the method proceeds directly to block 124 where the node vₚ for seeding is picked randomly from the set P=V_{S}^{(L)}, as in the method of FIG. 9. If however one or more degree-two check nodes are identified, the method then redefines the set P to include those variable nodes connected to the degree-two check nodes (in the example of FIG. 11, the variable nodes v₈ and v₁₁ which are connected to the degree-two check node c₇ would be included in the set P). The method then proceeds to block 124, where again one node is picked from the set P at random as the node vₚ.

From the foregoing, it should be appreciated that in the embodiment of FIG. 10, degree-two check nodes in the ESUCN code graph are particularly used as a criterion for selecting a candidate node vₚ for seeding. Based on empirical data⁴, Applicants have recognized and appreciated that in the exemplary scenarios described above in connection with FIGS. 10 and 11 (i.e., d_{B}_{_{S}}^{max=}1), those variable nodes in the set V_{S}^{(L)} that are connected to a degree-two check node in the set C_{E}^{(L)} are more suitable for seeding than other variable nodes in V_{S}^{(L)}. Hence, as discussed in Section 3 below, correcting these variable nodes has resulted in a significant improvement in decoder performance particularly in the error floor region.
₄ Simulations conducted in the error floor region using the (3,6) Margulis code with block length N=2640 discussed in connection with FIG. 5A revealed that often when the standard BP algorithm fails, all of the variable nodes in the set V_{S}^{(L)} have degree-one. Upon observation of the ESUCN code graph, it was noted that all of the satisfied check nodes had degree-one, with the exception of one degree-two check node. In many instances, correcting either of the two variable nodes connected to this check node resulted in noticeably improved performance.

In view of the foregoing, according to yet another implementation of the choice of variable node(s) logic 82, in one embodiment the decoder 500 may be more specifically tailored for decoding LDPC codes having higher code block lengths (e.g., see FIG. 5A) by utilizing reduced computational resources. In this embodiment, it is assumed that the performance of a standard BP algorithm in the waterfall region essentially is sufficient for the application at hand, and that decoding performance in this region may be relatively improved in cases of decoder error by picking a variable node from the SUCN code graph virtually at random for correction. Pursuant to this assumption, the method according to this embodiment focuses more particularly on the error floor region.

More specifically, in this embodiment, it is assumed that after an initial L iterations of the standard BP algorithm, virtually all decoding errors that occur in the error floor region result in an SUCN code graph including all degree-one variable nodes in the set V_{S}^{(L)}. Under this assumption, with reference again to the method of FIG. 10, essentially all of the blocks with the exception of block 122 may be omitted (except, of course, for the initial determination of the unsatisfied check nodes C_{S}^{(L)} in block 106). Accordingly, virtually the only processing required by the choice of variable node(s) logic in this embodiment would be that indicated in the block 122 shown in FIG. 10. Stated differently, a method for selecting a candidate variable node vₚ for seeding according to this embodiment would determine the set of unsatisfied check nodes C_{S}^{(L)}, determine the corresponding variable nodes V_{S}^{(L)}, determine the ESUCN code graph based on these variable nodes, and evaluate the degrees of the check-nodes in the set C_{E}^{(L)}. The method then would look for degree-two check nodes in the set C_{E}^{(L)}, and randomly select for correction one of the variable nodes connected to a degree-two check node in C_{E}^{(L)}. If no such degree-two check nodes are found, the method of this embodiment merely selects one of the variable nodes in the set V_{S}^{(L)} at random as the node vₚ for correction.

Having discussed several embodiments of the parity-check nodes logic 80 and the choice of variable node(s) logic 82 of the decoder shown in FIG. 6 (also see FIG. 6A, block 95), various issues regarding the type of correction that is employed for seeding the candidate variable node(s) are now addressed below.

b. Choosing the Logic State of a Seed

With reference again to FIG. 6, once one or more variable nodes vₚ (reference numeral 104) have been identified for correction by the choice of variable node(s) logic 82 according to various embodiments, the seeding logic 84 then seeds these one or more nodes with a maximum-certainty likelihood (also see FIG. 6A, block 97). In particular, one or more of the channel-based likelihoods 67 that normally are provided by the computation units 65 based on the received vector r (i.e., one or more elements of the set of messages O) is/are replaced by the seeding logic 84 with either a completely certain logic high state or a completely certain logic low state. These seeded values then are input to the one or more targeted variable nodes vₚ to provide revised variable node information for further iterations of the standard BP algorithm.

For purposes of this disclosure, a seed for a given candidate variable node vₚ is denoted as +S (representing a logic low state with complete certainty) or −S (representing a logic high state with complete certainty). In one aspect, this notation is derived from the general format of a log-likelihood message in a standard BP algorithm, expressed as log (p₀/p₁), where p₀ is the probability that a given node is a logic zero, and p₁ is the probability that a given node is a logic one (p₀+p₁=1). From the foregoing, it can be readily verified that as p₀ increases and p₁ decreases, the quotient tends to a very large number and the log of the quotient tends to +∞ (positive infinity); conversely, as p₀ decreases and p₁ increases, the quotient tends to a very small number and the log of the quotient tends to −∞ (negative infinity). In a practical implementation, infinity would be represented by some very large number S, deemed a “saturation value.” Hence, a completely certain logic low state (p₀₌1, p₁₌0) is represented by the log-likelihood +S, whereas a completely certain logic high state (p₀₌0, p₁₌1) is represented as the log-likelihood −S.

According to various embodiments, the seeding logic 84 may employ different criteria to decide the initial state O(vₚ)=±S of a seed for a given node vₚ. For example, in one embodiment, the seeding logic may select the state of the seed at random. In another embodiment, the seeding logic 84 may examine the a-priori channel-based log-likelihood for the node based on the received vector r (e.g., O(vₚ)=2rᵢ/σ² for an AWGN channel) and select the state of the seed based on the sign of the channel-based log-likelihood (e.g., if the sign is positive, assign +S and if the sign is negative, assign −S). In yet another embodiment, the seeding logic 84 may examine the log-likelihood value currently present at the node vₚ (i.e. after some number of iterations of the standard BP algorithm) and select the state of the seed based on the sign of this likelihood. In yet another embodiment, the seeding logic 84 may select the state of the seed based on some criteria that considers both the a-priori channel-based log-likelihood O(vₚ) input to the node vₚ, as well as the present log-likelihood at the node vₚ.

From the foregoing, it should be appreciated that a variety of decision criteria may be employed by the seeding logic 84 to decide the initial state of a seed for a given node, and that the invention is not limited to any particular manner of selecting the state of a seed.

c. Testing the Seed(s) using Extended BP Algorithms

Once one or more candidate variable nodes have been seeded by the seeding logic 84, the control logic 69 of the decoder 500 shown in FIG. 6 instructs the decoder block 50A to execute the standard BP algorithm for some predetermined number of additional iterations (also see FIG. 6A, block 99). Generally, the propagation of the seeded information throughout the bipartite graph with additional successive iterations in many cases yields a valid estimated code word \hat{x} where the standard BP algorithm originally produced a decoding error. As with the other components of the decoder 500, the control logic 69 may be configured to employ a variety of different processes for controlling the decoder block 50A to execute additional iterations of the standard BP algorithm using seeded information.

For example, in one embodiment, the control logic may essentially re-start the standard BP algorithm back “at the beginning,” i.e., by setting to zero the messages M={V, C, O} on the bipartite graph (reference FIG. 4) after the original L iterations, and re-initializing the variable nodes with the channel-based likelihoods O(vᵢ) for some nodes vᵢ and the seeded information O(vₚ)=±S for one or more other nodes vₚ. In one aspect of this embodiment, there is no need to utilize the messages M once one or more candidate variable nodes have been selected for seeding; hence, there may not be a need for significant storage resources to store the messages M for later use. Accordingly, in this embodiment, there may be minimal or virtually no requirements for the memory unit 86, which may facilitate a particular economic chip implementation of the decoder 500.

In other embodiments, the control logic may be configured to start the standard BP algorithm for additional iterations essentially “where it left off.” In one aspect of such embodiments, the memory unit 86 accordingly may be utilized to store and recall as necessary the messages M present on the bipartite graph after the original L iterations. In these embodiments, the control logic generally is configured to substitute only one or more of the channel-based likelihoods O(vₚ) with the appointed seeded information while maintaining the other messages M on the bipartite graph upon initiating additional iterations.

In either of the above scenarios, after performing a predetermined number of additional iterations of the standard BP algorithm with the initial seeded information, in some cases the algorithm still may not converge to yield a valid code word. In this event, again the control logic 69 may be configured to implement a number of different strategies for further action according to various embodiments.

For example, in one embodiment, the control logic may replace the initial seeded information with an opposite logic state. In particular, if a given node vₚ was initially seeded with +S and additional iterations of the algorithm failed to yield a valid code word, in one embodiment the node would be re-seeded with −S, followed by another round of additional iterations. As discussed above, in different embodiments the control logic may perform this next round of additional iterations either by “starting at the beginning” (i.e., zeroing out the messages M except for the channel-based likelihoods and re-seeded nodes), or restoring (i.e., from the memory unit 86 in FIG. 6) the messages M on the bipartite graph as they were at the end of the original L iterations, and then re-seeding before performing additional iterations using the restored messages.

If at this point the extended algorithm still fails to converge, according to one embodiment the control logic 69 may cause the selection of a different variable node for seeding. For example, with reference again to the embodiments discussed above in connection with FIGS. 9 and 10, the goal of the method shown in FIGS. 9 and 10 (with reference to the choice of variable node(s) logic 82) is to select a single variable node vₚ from the set Sᵥ^{max} ⊂V_{S}^{(L)} for seeding. If an extended algorithm still fails to converge after successively seeding this candidate node vₚ with both +S and −S and executing additional iterations, the control logic 69 may restore the messages on the bipartite graph as they were at the end of the original L iterations and select another node from the set Sᵥ^{max}⊂V_{S}^{(L)} (stored in the memory unit 86) for seeding by the seeding logic 84. In one aspect of this embodiment, if the set Sᵥ^{max} only contains one variable node, the control logic may select another variable node for seeding from the set V_{S}^{(L)}. Again, according to various aspects of this embodiment, the control logic 69 may be configured to select a different variable node from the set V_{S}^{(L)} either randomly or according to some “intelligent” criteria (e.g., the control logic may select the variable node in the set V_{S}^{(L)} having the next lowest degree compared to the originally selected variable node vₚ).

According to yet other embodiments, the control logic 69 in FIG. 6 may be configured to employ a “multiple-stage” approach to sequentially seed multiple different variable nodes if the +S and −S seeding of the initially selected variable node vₚ fails to cause the extended algorithm to converge. In some such “multiple-stage” embodiments, generally every time a given seed for a given variable node fails to yield a valid code word, a new set of unsatisfied check nodes is determined and a new candidate variable node for seeding is selected (e.g., pursuant to the methods of FIG. 9 or 10) and stored in the memory unit 86. Accordingly, for each different seed of a given candidate variable node, a failed convergence of the extended algorithm causes the selection of a new candidate variable node for seeding. In some embodiments, a “snapshot” of the messages M on the bipartite graph after each round of additional iterations also is taken and stored in the memory unit 86 for later use.

From the foregoing, it should be appreciated that in some multiple-stage embodiments, each candidate variable node for seeding may potentially implicate two other different variable nodes for future seeding (one new variable node for each seeded value that fails to cause convergence of the extended algorithm). Accordingly, a given stage j of such multiple-stage algorithms potentially generates 2^{j} other variable nodes for seeding in a subsequent stage (j+1).

Following below are more detailed explanations of two exemplary multiple-stage algorithms implemented by the decoder 500 according to various embodiments.

d. “Serial” Multi-stage Extended BP Algorithms

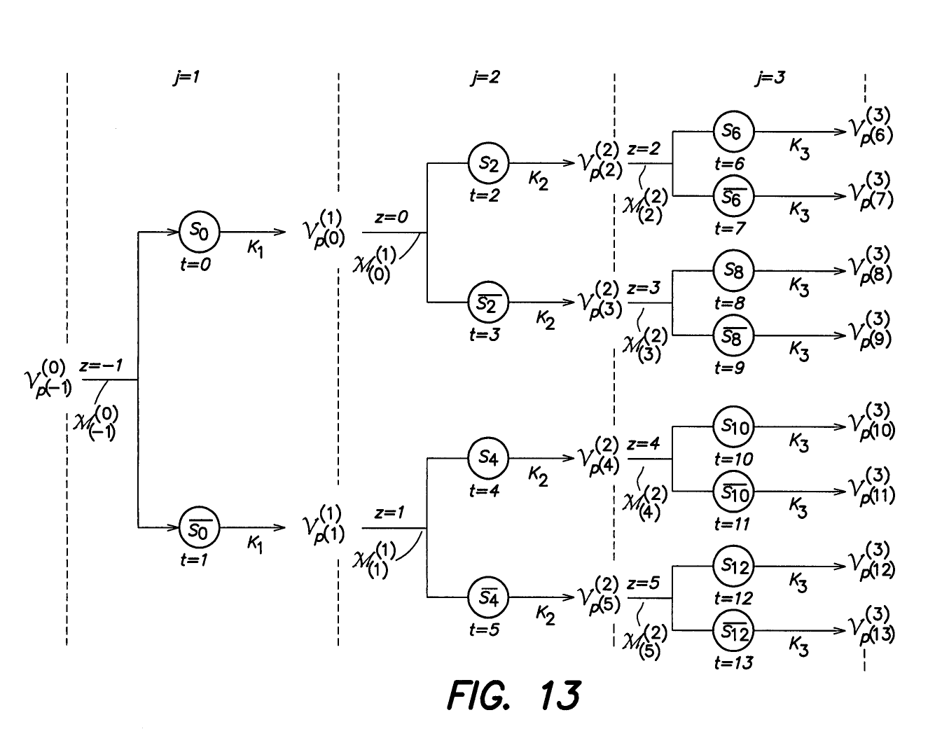

FIG. 12 is a flow chart illustrating an exemplary multiple-stage extended BP algorithm implemented by the decoder 500 shown in FIG. 6 according to one embodiment of the invention. As indicated in block 150 of FIG. 12, the extended BP algorithm according to this embodiment begins by setting the respective values for three parameters that may affect the complexity and performance of the algorithm. In one aspect of this embodiment, the values of these parameters may be varied by a user/operator to achieve a customized desired performance level for different applications. In another aspect, these parameters may be preset with predetermined values for a given decoder 500 such that the parameters are fixed during operation.

As shown in block 150 of FIG. 12, the three variable parameters that may affect the complexity and performance of the extended algorithm according to this embodiment are denoted as jₘₐₓ, L, and Kⱼ. As discussed above, the parameter L denotes the number of initial iterations of the standard BP algorithm before any seeding process. The parameter jₘₐₓ represents the maximum number of “stages” the extended algorithm may pass through upon failure of the standard BP algorithm after the initial L iterations. At each stage j(j=1, 2, . . . ,jₘₐₓ), the extended algorithm may potentially select and seed up to 2^{(j-1)} candidate variable nodes each with ±S seeds. With each new seed in place, the extended algorithm executes an additional Kⱼ iterations of the standard BP algorithm to see if the new seed causes the extended algorithm to converge. According to various aspects of this embodiment, the parameter Kⱼ indicated in block 150 of FIG. 12 may be chosen differently for each stage j=1, 2, . . . ,jₘₐₓ or may be set at the same value for each stage j(K₁=K₂= . . . Kⱼₘₐₓ).

For purposes of this embodiment, a “trial,” denoted by the counter t in FIGS. 6 and 12, refers to the process of seeding a given candidate variable node with either a +S or −S seed and performing Kⱼ additional iterations of the standard BP algorithm. Since as discussed above there are potentially 2^{(j-1)} candidate variable nodes for seeding during a given stage j, there may be up to 2^{j} trials during stage j (each candidate variable node may be successively seeded with +S and −S). In the embodiment of FIG. 12, as indicated in block 152, the extended algorithm is initialized at stage one (j←1) and the trial counter is initialized at zero (t←0).

As discussed further below, if during a given trial t at stage j the extended algorithm of FIG. 12 converges to yield a valid code word, the algorithm terminates successfully and provides as an output the estimated code word \hat{x}. If on the other hand the extended algorithm does not converge during the given trial t, a “snapshot” of the messages M={V, C, O} present on the bipartite graph is stored in the memory unit 86 as the message set

$${m}_{( t )}^{( j )} .$$

Based on the message set

$${m}_{( t )}^{( j )} ,$$

a new set of unsatisfied check nodes is determined and a new candidate variable node

$${v}_{p ( t )}^{( j )}$$

is selected (e.g., pursuant to the methods of FIG. 9 or 10) and also stored in the memory unit 86 for potential future seeding during the next stage j+1<jₘₐₓ.

In view of the foregoing, the method of FIG. 12 sequentially or “serially” tests multiple variable nodes in progressive stages until a valid code word results or until the stage jₘₐₓ is completed, whichever occurs first. According to one aspect of this embodiment, to ensure that a given variable node vᵢ is selected only once as a candidate node vₚ for seeding, the degree d_{B}_{_{S}} (vᵢ) of the variable node may be set to zero after selection for seeding for all subsequent determinations or calculations involving the node vᵢ (e.g., refer to the earlier discussion regarding the choice of variable node(s) logic 82 in connection with FIG. 8).

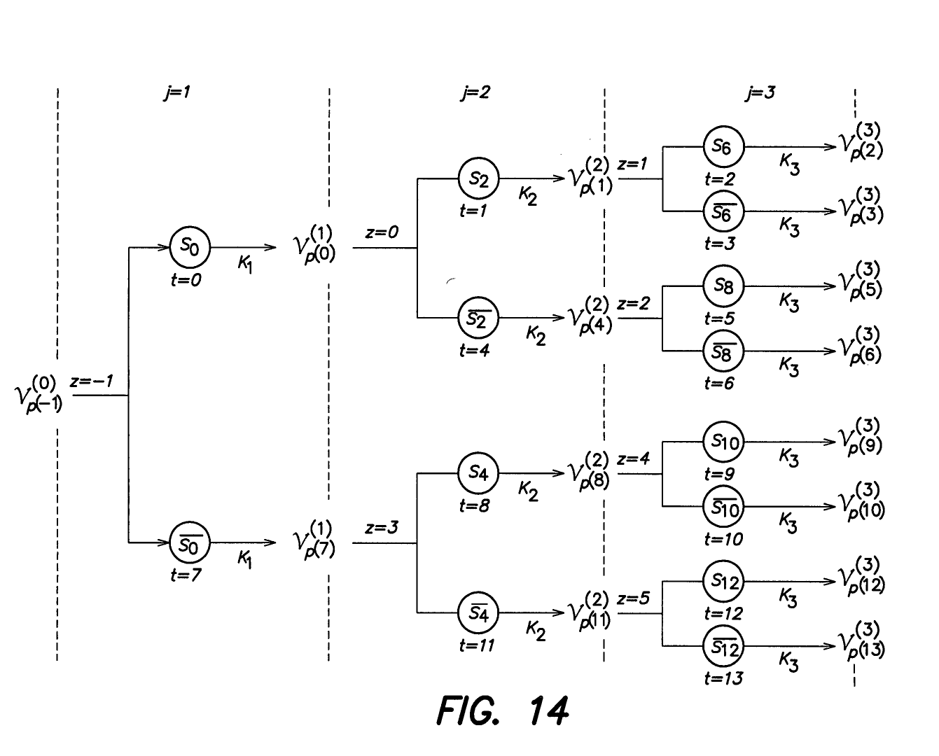

FIG. 13 is a “tree” diagram illustrating some of the concepts discussed immediately above in connection with the method of FIG. 12. In particular, FIG. 13 schematically illustrates an example of three stages (j=1, 2, 3) of a multi-stage serial approach pursuant to the method of FIG. 12 and using the notation introduced above. The tree diagram of FIG. 13 is referenced first to further explain some of the general concepts underlying the method of FIG. 12, followed by a more detailed explanation of the method. It should be appreciated that while FIG. 13 illustrates three stages of a multi-stage method, the invention is not limited in this respect, as the method may traverse a different number of stages with any given execution.

At the leftmost side of FIG. 13, the very first variable node

$${v}_{p ( t )}^{( j )}$$

that is selected for seeding after the initial L iterations of the standard BP algorithm is denoted as

$${v}_{p ( - 1 )}^{( 0 )}$$

(i.e., j=0, t=−1), to indicate that this first candidate variable node is selected before entering stage j=1 of the extended algorithm, and before the first trial t=0 is executed. The messages present on the bipartite graph after the initial L iterations but before execution of the extended algorithm are stored in memory as the message set

$${m}_{( - 1 )}^{( 0 )} .$$

During trial t=0 (indicated in the top left of FIG. 13), the first candidate node

$${v}_{p ( - 1 )}^{( 0 )}$$

is seeded with the value S₀ (i.e., the message set

$${m}_{( - 1 )}^{( 0 )}$$

is recalled from memory, and the channel-based message

$$o ( {v}_{p ( - 1 )}^{( 0 )} )$$

is replaced with S₀). With the seed S₀ in place, K₁ additional iterations of the standard BP algorithm are executed.

According to one aspect of this embodiment, the seed value S₀ for trial t=0 is calculated based on the sign of the channel-based log-likelihood that it replaces. In particular, Applicants have recognized and appreciated that the sign of the channel-based log-likelihood input to a given variable node is more likely to be correct than incorrect (this has been verified empirically). Thus, in one aspect, if the sign of the original channel-based log-likelihood

$$o ( {v}_{p ( - 1 )}^{( 0 )} )$$

is positive, it is replaced with the seed value S₀=+S; conversely, if the sign of

$$o ( {v}_{p ( - 1 )}^{( 0 )} )$$

is negative, it is replaced with the seed value S₀=−S. In another embodiment, the seed value S₀ may be chosen randomly to be either +S or −S. In yet another embodiment, the seed value S₀ may be chosen according to some other “intelligent” criteria (some examples of which are given above in Section 2b).

As discussed above, if upon seeding the node

$${v}_{p ( - 1 )}^{( 0 )}$$

with the seed value S₀ and executing an additional K₁ iterations the extended algorithm converges to yield a valid code word, the method exits the tree shown in FIG. 13 and terminates by providing a valid estimated code word \hat{x}. If however the extended algorithm fails to converge at this point, the messages present on the bipartite graph are stored as the message set

$${m}_{( 0 )}^{( 1 )}$$

(i.e., stage j=1, trial t=0). Also, a new candidate variable node

$${v}_{p ( 0 )}^{( 1 )}$$

is selected and stored in memory, based on the unsatisfied check nodes corresponding to the message set

$${m}_{( 0 )}^{( 1 )} .$$

The method then proceeds to trial t=1, as indicated in the lower left hand side of FIG. 13.

During trial t=1, the message set

$${m}_{( - 1 )}^{( 0 )}$$

and the first candidate node

$${v}_{p ( - 1 )}^{( 0 )}$$

after the initial L iterations of the standard BP algorithm are recalled from memory, and the node

$${v}_{p ( - 1 )}^{( 0 )}$$

is re-seeded with the opposite of the value S₀, denoted as \overline{S}₀ in FIG. 13. Another K₂ additional iterations of the standard BP algorithm then are executed. As above, if the extended algorithm converges at this point, it terminates and provides an estimated code word \hat{x}; if however the algorithm fails to converge, the messages present on the bipartite graph are stored as the message set

$${m}_{( 1 )}^{( 1 )}$$

(i.e., stage j=1, trial t=1), and a new candidate variable node

$${v}_{p ( 1 )}^{( 1 )}$$

is selected (based on the unsatisfied check nodes corresponding to this message set) and also stored in memory. The method then proceeds to stage j=2, trial t=2, as indicated in the upper middle section of FIG. 13.

During trial t=2 of stage j=2, as indicated in FIG. 13 the method recalls from memory the bipartite graph message set

$${m}_{( 0 )}^{( 1 )}$$

that was saved during the failed trial t=0 of the previous stage j=1, as well as the candidate variable node

$${v}_{p ( 0 )}^{( 1 )}$$

that was selected based on the unsatisfied check nodes corresponding to this message set. It should be appreciated that the formerly seeded value

$$O ( {v}_{p ( - 1 )}^{( 0 )} ) = {S}_{0}$$

from the previous stage is one of the messages in the recalled message set

$${m}_{( 0 )}^{( 1 )}$$

(i.e., in a given branch at a given stage, the seed(s) planted in the same branch in one or more previous stages are recalled). The method then seeds the new candidate variable node

$${v}_{p ( 0 )}^{( 1 )}$$

with the value S₂, and K₂ additional iterations of the standard BP algorithm are executed. Again, according to one aspect of this embodiment, the seed value S₂ may be calculated based on the sign of the channel-based log-likelihood that it replaces. In other aspects, the seed value S₂ may be chosen randomly or by some other intelligent criteria.

If upon seeding the node

$${v}_{p ( 0 )}^{( 1 )}$$

with the seed value S₂ and executing an additional K₂ iterations the extended algorithm converges to yield a valid code word, the method exits the tree shown in FIG. 13 and terminates by providing a valid estimated code word \hat{x}. If however the extended algorithm fails to converge at this point, the messages present on the bipartite graph are stored as the message set

$${m}_{( 2 )}^{( 2 )}$$

(i.e., stage j=2, trial t=2). Also, a new candidate variable node

$${v}_{p ( 2 )}^{( 2 )}$$

is selected and stored in memory, based on the unsatisfied check nodes corresponding to the message set

$${m}_{( 2 )}^{( 2 )} .$$

The method then proceeds to trial t=3, as indicated just below trial t=2 in FIG. 13.

During trial t=3, the message set

$${m}_{( 0 )}^{( 1 )}$$

and the candidate node

$${v}_{p ( 0 )}^{( 1 )}$$

after the failed trial t=0 again are recalled from memory, and the node

$${v}_{p ( 0 )}^{( 1 )}$$

is re-seeded with the opposite of the value S₂, denoted as \overline{S}₂ in FIG. 13. Another K₂ additional iterations of the standard BP algorithm then are executed. As above, if the extended algorithm converges at this point, it terminates and provides an estimated code word \hat{x}; if however the algorithm fails to converge, the messages present on the bipartite graph are stored as the message set

$${m}_{( 3 )}^{( 2 )}$$

(i.e., stage j=2, trial t=3), and a new candidate variable node

$${v}_{p ( 3 )}^{( 2 )}$$

is selected (based on the unsatisfied check nodes corresponding to this message set) and also stored in memory. The method then proceeds to stage j=2, trial t=4, as indicated in the lower middle section of FIG. 13, where the message set

$${m}_{( 1 )}^{( 1 )}$$

and the candidate node

$${v}_{p ( 1 )}^{( 1 )}$$

after the failed trial t=1 are recalled from memory, and the node

$${v}_{p ( 1 )}^{( 1 )}$$

is seeded and tested as discussed above.

From the foregoing, it may be readily appreciated with the aid of FIG. 13 how the method of FIG. 12 continues to conduct successive trials and proceed through successive stages of seeding candidate variable nodes until the algorithm converges or reaches the stage jₘₐₓ. Following below is a more detailed discussion of an exemplary implementation of the method outlined in FIG. 12.

With reference again to FIG. 12, as discussed above the method begins in block 150 with the setting of the parameters jₘₐₓ, L and Kⱼ. In block 152, the stage j is initialized at j=1 and the trial t is initialized at t=0. In block 154, the initial L iterations of the standard BP algorithm are executed, and in block 156, the set of unsatisfied check nodes C_{S}^{(L)} after L iterations is determined. If there are no unsatisfied check nodes (i.e., C_{S}^{(L)}=φ; null set), then the standard BP algorithm was successful at providing a valid code word, and the method terminates, as indicated in block 158. If however there are any unsatisfied check nodes after the initial L iterations, the method proceeds to block 160.

In block 160, the messages on the bipartite graph after the initial L iterations are stored as

$${m}_{( - 1 )}^{( 0 )} ,$$

and a parameter I indicating the total number of iterations is initialized to I=L. The set of unsatisfied check nodes C_{S}^{(l)} is determined, and the candidate variable node vₚ for seeding is selected (e.g., pursuant to the method of FIG. 9 or 10) and stored as

$${v}_{p ( - 1 )}^{( 0 )} .$$

In block 162, a parameter z, representing the total number of candidate variable nodes tested, is initialized at z=−1 (the parameter z is also indicated along the various branches of the tree diagram of FIG. 13). Stated differently, the total number of candidate variable nodes that have been tested at any given point during the method of FIG. 12 is given by the quantity z+2. As indicated in block 162, with each new trial t the parameter z is updated according to the formula z=└(t/2)−1┘, where the brackets └ ┘ denote the largest integer smaller than or equal to the quantity between the brackets. Once the parameter z is updated, the recorded values

$${m}_{( z )}^{( j - 1 )}$$

are recalled from memory and restored on the bipartite graph. At this point in the present example (j=1, z=−1), this corresponds to the message set

$${m}_{( - 1 )}^{( 0 )} .$$

In block 164 of FIG. 12, the degree of the selected variable node

$${v}_{p ( z )}^{( j - 1 )}$$

(at this point,

$${v}_{p ( - 1 )}^{( 0 )} )$$

is set to zero so that this variable node is not selected again during a subsequent trial. Also, the method seeds the candidate variable node with the saturation value corresponding to the sign of the channel-based likelihood

$$O ( {v}_{p ( z )}^{( j - 1 )} ) .$$

More specifically, the channel-based likelihood

$$O ( {v}_{p ( z )}^{( j - 1 )} )$$

is replaced with the maximum certainty likelihood seed given by sgn

$$\{ O ( {v}_{p ( z )}^{( j - 1 )} ) \} \cdot + S [ 1 - 2 ( t mod 2 ) ] ,$$

where the trial parameter t is used to flip the sign of the seed with alternating trials.

In block 166 of FIG. 12, an additional Kⱼ iterations of the standard BP algorithm are executed with the recalled messages and seed in place, and the iteration parameter I is updated to I=I+Kⱼ. After the additional Kⱼ iterations, the method examines the new set of unsatisfied check nodes

$${C}_{S}^{( I )}$$

If there are no unsatisfied check nodes, the extended algorithm was successful at providing a valid code word, as indicated in block 168, and the method terminates by outputting the estimated code word \hat{x}, as indicated in block 170. If however there are unsatisfied check nodes in the set

$${C}_{S}^{( I )}$$

the method proceeds to block 172, where the current messages on the graph are stored as

$${M}_{( t )}^{( j )}$$

and a new variable node for seeding is determined based on

$${C}_{S}^{( I )}$$

(e.g., pursuant to the methods of FIG. 9 or 10) and stored as

$${v}_{p ( t )}^{( j )} ,$$

thus completing this trial.

In block 174 of FIG. 12, the trial parameter t is accordingly incremented (t←t+1), and in block 176 the method asks if all of the trials at a given stage have been completed (i.e., does t=2^{j+1}−2 ?). If the answer to this question is yes, the stage j is incremented in block 178 (j←j+1); otherwise, block 178 is bypassed. The method then proceeds to block 180, where it asks if the stage j has been incremented beyond jₘₐₓ. If yes, then the method terminates in block 182 without having found a valid codeword. Otherwise, the method returns to block 162 to appropriately update the tested variable node counter z and recall the appropriate messages M from memory for the next trial of testing.

With respect to memory requirements, in one aspect the method of FIG. 12 may be somewhat memory intensive in that upon the completion of each stage j, the method potentially needs to store 2^{j} bipartite graph message sets M. This may be readily verified with the aid of FIG. 13; in particular, with reference to FIG. 13, if the method of FIG. 12 completes stage j=1, it will have stored two message sets

$$( i . e . , {M}_{( 0 )}^{( 1 )} and {M}_{( 1 )}^{( 1 )} ) .$$

At the end of stage j=2, the method will have stored four message sets, and at the end of stage j=3 the method will have stored eight message sets. Accordingly, to implement the decoder 500 of FIG. 6 such that it performs the method of FIG. 12, the memory unit 86 needs to be appropriately sized to accommodate at least 2^{j/max} bipartite graph message sets M.

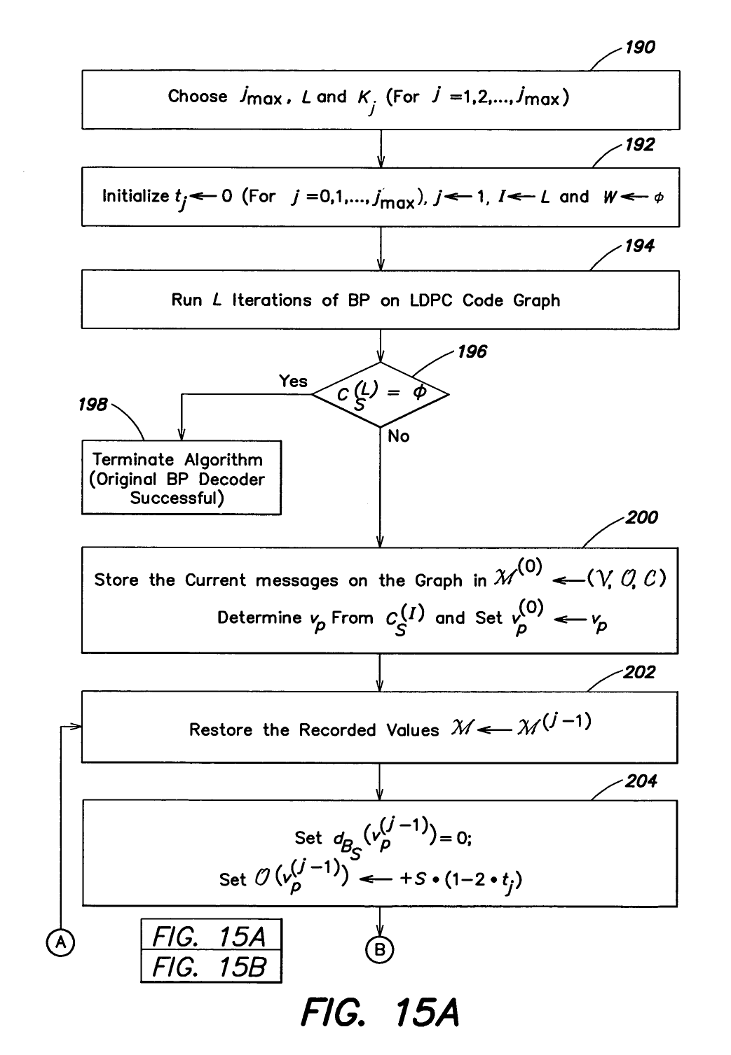

According to another embodiment, a multiple-stage extended BP algorithm similar to FIG. 12 may be serially-executed in a different manner so as to require less memory resources than the method of FIG. 12. FIG. 14 is a tree diagram similar to the diagram of FIG. 13 that is used as an aid to explain this embodiment. In the example of FIG. 14, for purposes of the present explanation it is assumed that jₘₐₓ₌3, so that FIG. 14 represents the total number of trials t that the method traverses if no valid code words are found. It should be appreciated, however, that the method of this embodiment is not limited to a maximum number of three stages, and that other values of jₘₐₓ may be chosen in other examples.

One of the salient differences between the tree diagrams of FIGS. 13 and 14 is that the order of the trials t is different. For example, as illustrated in FIG. 13 and discussed above, the method of FIG. 12 only proceeds to a subsequent stage j+1 after it has tested all possible candidate variable nodes vₚ in stage j with all possible seeds ±S. As the method of FIG. 12 successively advances through the stages j=1, 2, 3 . . . jₘₐₓ, it may terminate at any time upon converging to find a valid code word (i.e., in some cases before reaching the stage jₘₐₓ).

Unlike the method of FIG. 12, however, the method of this embodiment, as schematically depicted in FIG. 14, proceeds all the way through a given branch of the tree diagram until it reaches the stage jₘₐₓ or decodes a valid code word, whichever occurs first. Once the method of this embodiment reaches the stage jₘₐₓ for a given branch of the tree, it tests both seeds and, if no code word is found, then retreats back to the previous stage. Once back at the previous stage, the method then proceeds forward again toward the stage jₘₐₓ down a different branch of the tree. The method continues in this fashion until all branches of the tree are traversed, or until a valid code word is found, whichever occurs first. This pattern of tree branch traversal may be observed in FIG. 14 by the progression of the trial counter t.

In the embodiment of FIG. 14, the memory unit 86 of the decoder 500 shown in FIG. 6 need only accommodate a single bipartite message set M for each stage j. Hence, instead of requiring memory resources for 2^{jmax} message sets t as in the embodiment represented in FIGS. 12 and 13, the embodiment of FIG. 14 requires memory resources for only jₘₐₓ message sets M. For example, with reference to stage j=3 in FIG. 14, it should be readily observed that based on the pattern of tree branch traversal, the message set M utilized in trials t=12 and 13 may overwrite the memory space required for the message set M utilized in trials t=9 and 10, as the latter message set is no longer required once trial t=10 is completed. Similarly, the message set utilized in trials t=9 and 10 may overwrite the memory space required for the message set utilized in trials t=5 and 6, as again the latter message set is no longer required once trial t=6 is completed. In this manner, it may be verified that at each stage j in the embodiment of FIG. 14, the memory need only accommodate one message set M.

While the embodiment of FIG. 14 arguably is less memory-intensive than the embodiment represented in FIGS. 12 and 13, it should be appreciated that the method of FIG. 12 in some cases may be more computationally efficient, in that it completely tests all possibilities in a given stage before moving onto the next stage. Hence, in one aspect, the embodiments of FIGS. 12, 13 and 14 represent a design-choice tradeoff between memory conservation and computational efficiency.

In yet another embodiment of a serially-executed extended algorithm similar to those of FIGS. 12, 13 and 14, the control unit 69 of the decoder 500 shown in FIG. 6 may be configured such that virtually no memory resources are utilized to accommodate storage of any full bipartite graph message sets M. For example, in this embodiment, upon the failure of any given trial t, a new variable node for correction is selected based on the SUCN code graph, the messages on the graph then are zeroed-out, and the new variable node is appropriately seeded. Additionally, the channel-based likelihoods of all previously corrected variable nodes in the same branch of the tree are initialized at their previously seeded values, and the remaining variable nodes are initialized with their respective a-priori channel-based likelihoods. With the bipartite graph thusly prepared, a new trial is then conducted by executing an additional number of iterations. In the foregoing manner, memory resources may be significantly conserved for a given design implementation of the decoder 500.

e. “Parallel” Multi-stage Extended BP Algorithm

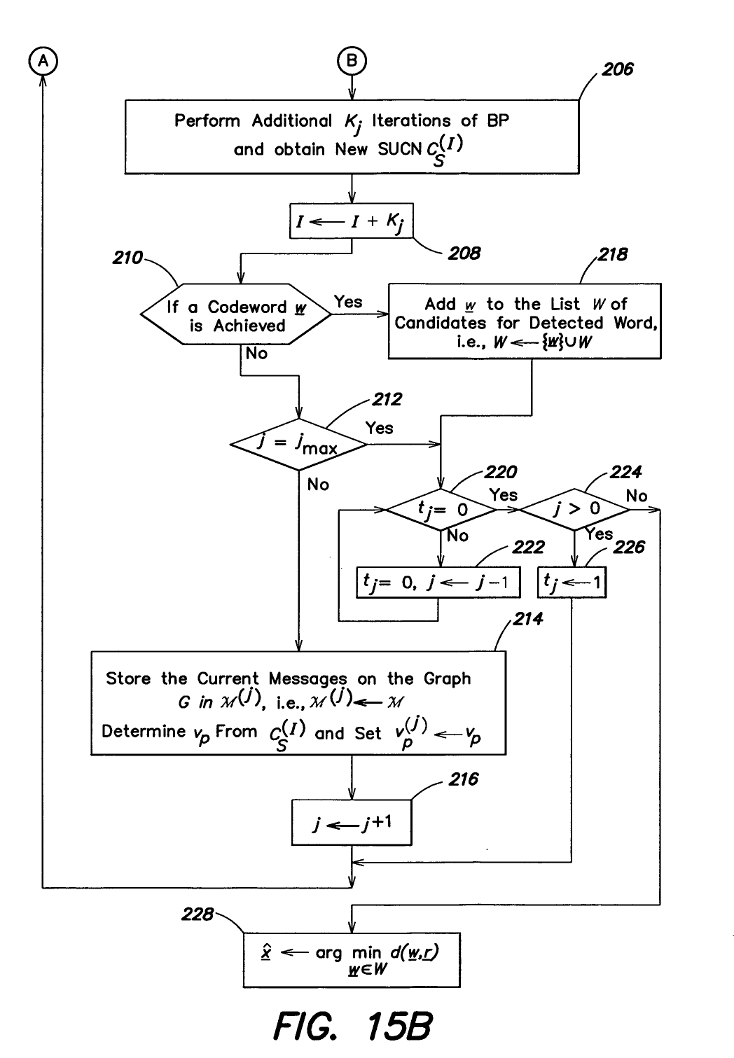

FIG. 15 is a flow chart illustrating yet another exemplary multiple-stage extended BP algorithm implemented by the decoder 500 shown in FIG. 6 according to one embodiment of the invention. In various aspects, the method of FIG. 15 draws on elements of the different “serial” multi-stage algorithms discussed above in connection with FIGS. 12-14. However, unlike the serial algorithms, the method of FIG. 15 does not automatically terminate upon decoding a valid code word, but rather continues executing multiple trials until reaching stage jₘₐₓ, even if a valid code word is decoded in a given trial. As valid code words are decoded in the method of FIG. 15, they are maintained in a list of candidate code words stored in memory; as discussed further below, in this embodiment, valid code words decoded during various trials are denoted as w, and the list of candidate code words maintained in memory is denoted as W.

According to one aspect of this embodiment, when the method of FIG. 15 completes executing trials at all stages j≦jₘₐₓ, the method then selects one code word w from the list of candidate code words W which minimizes the Euclidean distance between the code word w and the received vector r. This code word w then is provided as the estimated code word \hat{x}. Because the method of FIG. 15 executes trials at all stages j≦jₘₐₓ before making a decision as to the estimated code word \hat{x}, it is said to consider the results of all stages “in parallel.” Hence, in this embodiment, although trials are still executed successively or “serially,” for purposes of this disclosure the embodiment of FIG. 15 is referred to as a “parallel” multiple-stage extended algorithm to distinguish it from the embodiments of FIGS. 12-14.

Many of the blocks in the flow chart of FIG. 15 involve acts similar to those discussed above in connection with FIG. 12. At least one salient difference should be noted, however, in the use of the parameter tⱼ in the method of FIG. 15. In particular, unlike the trial counter t in the method of FIG. 12 which indicates the total number of trials executed at a given point in the method, the parameter tⱼ in the method of FIG. 15 either has a value of one or zero, and is employed at a given stagej to indicate the state of a seed (±S) that is being tested during a given trial. As will be appreciated from the discussion below, the method of FIG. 15 employs the parameter tⱼ to facilitate an execution of successive trials that follows the tree-branch traversal progression illustrated in FIG. 14 (e.g., so as to conserve memory resources required for the algorithm).

With reference to FIG. 15, the acts illustrated in blocks 190, 192, 194, 196 and 198 are substantially similar to acts discussed in connection with FIG. 12. For example, in block 190 of FIG. 15, again variable parameters jₘₐₓ, L, and Kⱼ are initialized, and may be adjusted or fixed in various implementations based on a desired complexity and/or performance of the algorithm. In block 192, the parameter tⱼ is initialized at zero, the stage j is initialized at one, the iteration counter I is initialized at L, and the set of candidate code words W is initialized as a null set. In block 194, L iterations of the standard BP algorithm are executed, and in block 196 the set of unsatisfied check nodes is determined. If there are no unsatisfied check nodes, the method terminates in block 198, as a valid code word is determined by the standard BP algorithm.

Likewise, blocks 200, 202, 204, 206 and 208 are similar to corresponding blocks of FIG. 12. At least one noteworthy difference in these blocks, however, is illustrated in block 204, in which a channel-based likelihood O(v_{P}^{(j-1)}) is seeded with a maximum-certainty likelihood. In particular, the seeded likelihood in block 204 does not depend on the a-priori channel-based likelihood that it replaces (as in FIG. 12), but rather is determined merely by the state of the parameter tⱼ (again, which is either one or zero). In this manner, the parameter tⱼ serves to toggle the state of the seed in successive trials at the same stage j irrespective of the a-prior channel-based likelihood.

The blocks 210, 212, 214, 216, 218, 220, 222, 224 and 226 of FIG. 15 are designed to continue traversing throughj stages of a tree diagram in a manner similar to that discussed above in connection with FIG. 14, until multiple trials are executed at all stages j≦jₘₐₓ. After each trial, if a valid code word is decoded (see block 210) it is denoted as w and added to a list W of candidate code words (see block 218). When all stages j≦jₘₐₓ have been traversed, in block 228 the method outputs as an estimated code word \hat{x} one code word w from the list of candidate code words W which minimizes the Euclidean distance between the code word w and the received vector r

$$( i . e . , \hat{\underline{x}} ← arg {min}_{\underline{w} ∈ W} d ( \underline{w} , \underline{r} ) ) .$$

In one aspect, the “parallel” multiple-stage method of FIG. 15 may in some cases be more computationally intensive than the “serial” methods of FIGS. 12-14 in that all stages j≦jₘₐₓ always are traversed. Hence, for large jₘₐₓ, the parallel method may be significantly more computationally intensive. However, as discussed below in Section 3, the decoding performance of the parallel method generally is noticeably better than that of a serial method using the same parameters jₘₐₓ, L, and Kⱼ, and significantly approaches that of the theoretically optimum maximum-likelihood decoding scheme. It should also be appreciated, though, that a serial multi-stage method (as in FIGS. 12-14) may be implemented that essentially simulates the performance of a parallel multi-stage method (i.e., also approaching the theoretically optimum maximum-likelihood decoding scheme) by choosing a higher jₘₐₓ for the serial method. Hence, in various embodiments, the parameters jₘₐₓ, L, and Kⱼ, as well as the options of serial and parallel methods, provide a number of different possibilities for flexibly implementing an improved decoding scheme for a number of different applications.

3. Experimental Results

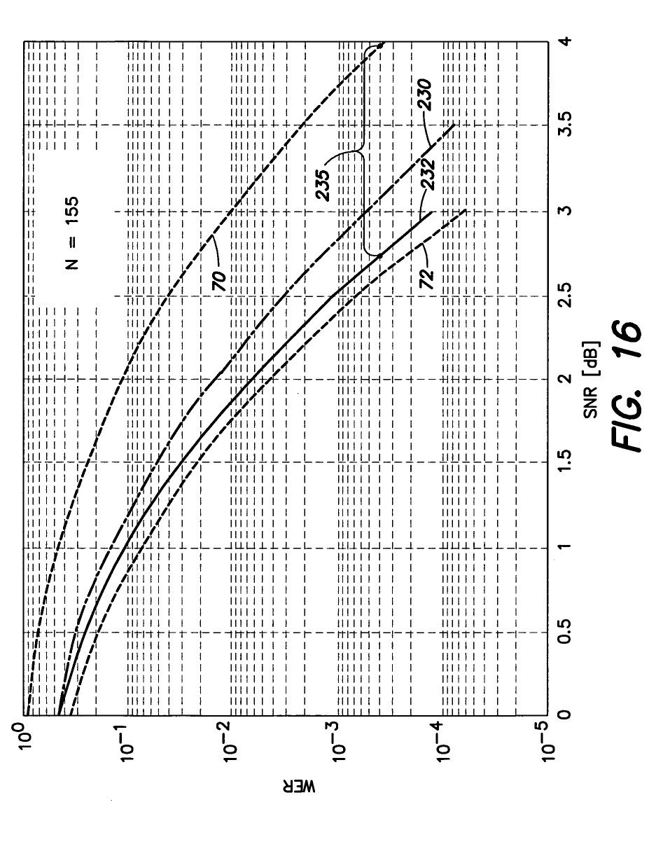

FIG. 16 is a graph illustrating the comparative performance of a simulated conventional maximum-likelihood (ML) decoder (reference numeral 72), a simulated conventional belief-propagation (BP) decoder (reference numeral 70), an improved decoder according to one embodiment of the invention that executes the “serial” multiple-stage method of FIG. 12 (reference numeral 230), and an improved decoder according to another embodiment of the invention that executes the “parallel” multiple-stage method of FIG. 15 (reference numeral 232). The simulation conditions for the decoders represented in FIG. 16 are identical to those for the simulations of FIG. 5; namely, a Tanner code with N=155 transmitted over an AWGN channel was used for each simulation.

For both the “serial” improved decoding method represented by curve 230 and the “parallel” improved decoding method represented by curve 232 in FIG. 16, the method of FIG. 9 was employed to determine a candidate variable node for seeding at each trial (other simulations under similar conditions employing the method of FIG. 10 for determining a candidate variable node for seeding at each trial produced similar performance results for the N=155 Tanner code). Also, for both the serial and parallel improved decoding methods represented in FIG. 16, the following parameters were used: L=1 00, K₁=K₂= . . . . =Kⱼₘₐₓ=20, and jₘₐₓ=11.

As can be readily observed in FIG. 16, both the serial and parallel improved decoding methods according to the present invention resulted in significantly improved performance as compared to a standard BP decoding algorithm executed by a conventional BP decoder. In particular, the parallel improved decoding method represented by curve 232 almost achieves the ML decoding performance represented by curve 72, and both the serial and parallel improved decoding methods outperform the conventional BP decoder by at least 1 dB or more at a word error rate (WER) of 4×10⁻⁴ (see reference numeral 235).

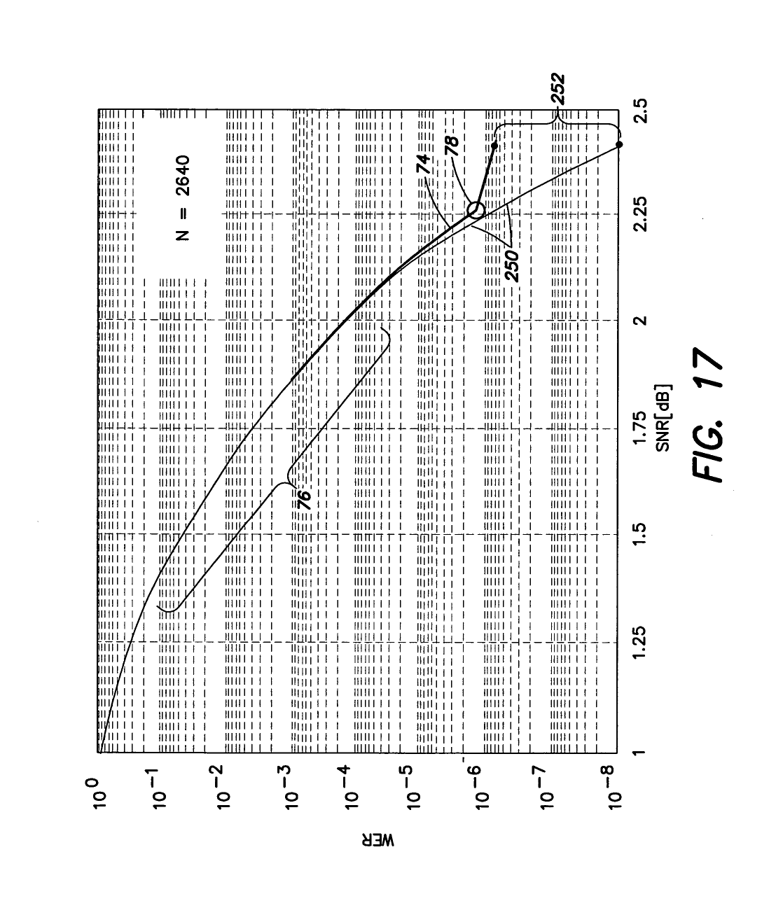

FIG. 17 is another graph illustrating the comparative performance for LDPC codes having higher code block lengths of the simulated conventional belief-propagation (BP) decoder shown in FIG. 5A, and an improved decoder according to one embodiment of the invention. In particular, the simulation conditions for both decoders represented in FIG. 17 are identical to those for the simulation of FIG. 5A, namely, a Margulis code with N=2640 transmitted over an AWGN channel.

As in the simulation of FIG. 5A, the graph of FIG. 17 shows the performance curve 74 of the conventional BP decoder, including the waterfall region 76 and the error floor 78. Superimposed on the performance curve 74 is a second performance curve 250 corresponding to an improved decoder according to one embodiment of the invention. As can be readily observed from the performance curves 74 and 250 in FIG. 17, although the two decoders perform similarly in the waterfall region 76, the improved decoder achieves significantly better performance at higher SNR, i.e., corresponding to the error floor region of the conventional decoder.

For the improved decoding method represented by curve 250 in FIG. 17, a serial multiple-stage algorithm as discussed above in connection with FIG. 12 was employed with the parameters L=200, K₁=K₂= . . . . =Kⱼₘₐₓ₌20, and jₘₐₓ₌5, and using the method of FIG. 10 to determine a candidate variable node for seeding at each trial.

As shown in FIG. 17, again dramatic performance improvement is achieved especially in the area corresponding to the error floor region of the conventional BP decoder. In particular, the error floor 78 of the simulated conventional BP decoder occurs at a SNR of just over 2.25 dB, corresponding to a word error rate of just over 10⁶. By contrast, no change in slope of the curve 250 is observed corresponding to an error floor; rather, the word error rate of the curve 250 continues to decrease at an accelerated rate as the SNR is increased. Hence, in the improved decoder represented in FIG. 17, the error floor is virtually eliminated. More specifically, at a SNR of approximately 2.4 dB, the improved decoder of FIG. 17 achieves a word error rate of 10⁻⁸, whereas the conventional BP decoder represented in FIG. 5A achieves a word error rate of approximately 10⁻⁶, thus constituting an improvement of approximately two orders of magnitude in the error floor region of the conventional decoder (see reference numeral 252).

4. Conclusion

As discussed earlier, Applicants have recognized and appreciated that there is a wide range of applications for improved decoding methods and apparatus according to the present invention. For example, conventional LDPC coding schemes already have been employed in various information transmission environments such as telecommunications and storage systems. More specific examples of system environments in which LDPC encoding/decoding schemes have been adopted or are expected to be adopted include, but are not limited to, wireless (mobile) networks, satellite communication systems, optical communication systems, and data recording and storage systems (e.g., CDs, DVDs, hard drives, etc.).

In each of these information transmission environments, significantly improved decoding performance may be realized pursuant to methods and apparatus according to the present invention. Such performance improvements in communications systems enable significant increases of data transmission rates or significantly lower power requirements for information carrier signals. For example, improved decoding performance enables significantly higher data rates in a given channel bandwidth for a system-specified signal-to-noise ratio; alternatively, the same data rate may be enabled in a given channel bandwidth at a significantly lower signal-to-noise ratio (i.e., lower carrier signal power requirements). For data storage applications, improved decoding performance enables significantly increased storage capacity, in that a given amount of information may be stored more densely (i.e., in a smaller area) on a storage medium and nonetheless reliably recovered (read) from the storage medium.

Having thus described several illustrative embodiments, it is to be appreciated that various alterations, modifications, and improvements will readily occur to those skilled in the art. Such alterations, modifications, and improvements are intended to be part of this disclosure, and are intended to be within the spirit and scope of this disclosure. While some examples presented herein involve specific combinations of functions or structural elements, it should be understood that those functions and elements may be combined in other ways according to the present invention to accomplish the same or different objectives. In particular, acts, elements, and features discussed in connection with one embodiment are not intended to be excluded from similar or other roles in other embodiments. Accordingly, the foregoing description and attached drawings are by way of example only, and are not intended to be limiting.

1. A decoding method for a linear block code having a parity check matrix that is sparse or capable of being sparsified, the decoding method comprising an act of:
A) modifying a conventional decoding algorithm for the linear block code such that a performance of the modified decoding algorithm significantly approaches or more closely approximates a performance of a maximum-likelihood decoding algorithm for the linear block code.

2. The method of claim 1, wherein the act A) includes an act of:
modifying the conventional decoding algorithm for the linear block code such that the performance of the modified decoding algorithm in at least an error floor region significantly approaches or more closely approximates the performance of a maximum-likelihood decoding algorithm for the linear block code.

3. The method of claim 1, wherein the conventional decoding algorithm is an iterative decoding algorithm, and wherein the act A) includes at least one of the following acts:
B) modifying the iterative decoding algorithm such that a decoding error probability of the modified iterative decoding algorithm is significantly decreased from a decoding error probability of the unmodified iterative decoding algorithm at a given signal-to-noise ratio; and
C) modifying the iterative decoding algorithm such that an error floor of the modified iterative decoding algorithm is significantly decreased or substantially eliminated as compared to an error floor of the unmodified iterative decoding algorithm.

4. The method of claim 3, wherein either of the acts B) or C) includes the following acts:
D) executing the iterative decoding algorithm for a predetermined number of iterations;
E) upon failure of the iterative decoding algorithm to provide valid decoded information after the predetermined first number of iterations, altering at least one value used by the iterative decoding algorithm; and
F) executing at least a first round of additional iterations of the iterative decoding algorithm using the at least one altered value.

5. The method of claim 4, wherein the iterative decoding algorithm is a message-passing algorithm, and wherein:
the act D) includes an act of executing the message-passing algorithm for the predetermined first number of iterations to attempt to decode the received information;
the act E) includes an act of, upon failure of the message-passing algorithm to provide valid decoded information after the predetermined first number of iterations, altering the at least one value used by the message-passing algorithm; and
the act F) includes an act of executing at least the first round of additional iterations of the message-passing algorithm using the at least one altered value.

6. The method of claim 1, wherein the linear block code is a low-density parity check (LDPC) code, wherein the conventional decoding algorithm is a standard belief-propagation (BP) algorithm based on a bipartite graph for the LDPC code, and wherein the act A) includes at least one of the following acts:
B) modifying the standard BP algorithm such that a decoding error probability of the modified BP algorithm is significantly decreased from a decoding error probability of the standard BP algorithm at a given signal-to-noise ratio; and
C) modifying the standard BP algorithm such that an error floor of the modified BP algorithm is significantly decreased or substantially eliminated as compared to an error floor of the standard BP algorithm.

7. The method of claim 6, wherein either of the acts B) or C) includes the following acts:
D) executing the standard BP algorithm for a predetermined number of iterations;
E) upon failure of the standard BP algorithm after the predetermined number of iterations, selecting at least one candidate variable node of the bipartite graph for correction;
F) seeding the at least one candidate variable node with a maximum-certainty likelihood; and
G) executing additional iterations of the standard BP algorithm.

8. A method for decoding received information encoded using a coding scheme, the method comprising acts of:
A) executing an iterative decoding algorithm for a predetermined first number of iterations to attempt to decode the received information;
B) upon failure of the iterative decoding algorithm to provide valid decoded information after the predetermined first number of iterations, altering at least one value used by the iterative decoding algorithm; and
C) executing at least a first round of additional iterations of the iterative decoding algorithm using the at least one altered value.

9. The method of claim 8, wherein the iterative decoding algorithm is a message-passing algorithm, and wherein:
the act A) includes an act of executing the message-passing algorithm for the predetermined first number of iterations to attempt to decode the received information;
the act B) includes an act of, upon failure of the message-passing algorithm to provide valid decoded information after the predetermined first number of iterations, altering at least one value used by the message-passing algorithm; and
the act C) includes an act of executing at least the first round of additional iterations of the message-passing algorithm using the at least one altered value.

10. The method of claim 9, wherein the coding scheme is a low-density parity check (LDPC) coding scheme, and wherein the message-passing algorithm is a standard belief-propagation (BP) algorithm.

11. The method of claim 9, wherein before the act A), the method includes an act of:
receiving the received information from a coding channel that includes at least one data storage medium.

12. The method of claim 9, wherein before the act A), the method includes an act of:
receiving the received information from a coding channel that is configured for use in a wireless communication system.

13. The method of claim 9, wherein before the act A), the method includes an act of:
receiving the received information from a coding channel that is configured for use in a satellite communication system.

14. The method of claim 9, wherein before the act A), the method includes an act of:
receiving the received information from a coding channel that is configured for use in an optical communication system.

15. The method of claim 9, wherein the message-passing algorithm is based on a bipartite graph for the coding scheme, and wherein the act B) includes an act of:
altering at least one likelihood value associated with at least one check node of the bipartite graph.

16. The method of claim 9, wherein the message-passing algorithm is based on a bipartite graph for the coding scheme, and wherein the act B) includes an act of:
B1) altering at least one likelihood value associated with at least one variable node of the bipartite graph.

17. The method of claim 16, wherein the act B1) includes acts of:
D) selecting at least one candidate variable node of the bipartite graph for correction; and
E) seeding the at least one candidate variable node with the at least one altered likelihood value.

18. The method of claim 17, wherein the act D) includes acts of:
D1) determining a set of unsatisfied check nodes of the bipartite graph, the set including at least one unsatisfied check node; and
D2) selecting the at least one candidate variable node based at least in part on the set of unsatisfied check nodes.

19. The method of claim 18, wherein the act D1) includes acts of:
calculating a syndrome of an estimated invalid code word provided by the standard message-passing algorithm after the predetermined first number of iterations; and
determining the set of unsatisfied check nodes based on the syndrome.

20. The method of claim 18, wherein the act D1) includes an act of:
determining the set of unsatisfied check nodes based on aggregate likelihood information from all of the check nodes of the bipartite graph.

21. The method of claim 18, wherein the act D2) includes acts of:
determining a set of variable nodes associated with the set of unsatisfied check nodes, the set of variable nodes including at least one variable node; and
selecting the at least one candidate variable node randomly from the set of variable nodes.

22. The method of claim 18, wherein the act D2) includes acts of:
D3) determining a set of variable nodes associated with the set of unsatisfied check nodes, the set of variable nodes including at least one variable node; and
D4) selecting the at least one candidate variable node from the set of variable nodes according to a prescribed algorithm.

23. The method of claim 22, wherein the act D4) includes an act of:
determining a set of highest-degree variable nodes from the set of variable nodes.

24. The method of claim 23, further including an act of:
selecting the at least one candidate variable node randomly from the set of highest-degree variable nodes.

25. The method of claim 23, further including an act of:
D5) selecting the at least one candidate variable node intelligently from the set of highest-degree variable nodes.

26. The method of claim 25, wherein the act D5) includes an act of:
D6) selecting the at least one candidate variable node based at least in part on at least one neighbor of at least one variable node in the set of highest-degree variable nodes.

27. The method of claim 26, wherein the act D6) includes acts of:
determining all neighbors for each variable node in the set of highest-degree variable nodes;
determining the degree of each neighbor; and
for each degree, determining the number of neighbors having a same degree.

28. The method of claim 27, wherein the act D6) further includes acts of:
determining the highest degree for which only one variable node in the set of highest-degree variable nodes has the smallest number of neighbors; and
selecting the one variable node as the at least one candidate variable node.

29. The method of claim 27, wherein the act D6) further includes acts of:
determining the highest degree for which only two variable nodes in the set of highest-degree variable nodes have the smallest number of neighbors;
examining a number of neighbors for each of the two variable nodes at at least one lower degree;
identifying one variable node of the two variable nodes with the fewer number of neighbors at the next lowest degree at which the two variable nodes have different numbers of neighbors; and
selecting the one variable node as the at least one candidate variable node.

30. The method of claim 22, further including acts of:
determining an extended set of unsatisfied check nodes based on the set of variable nodes associated with the set of unsatisfied check nodes;
identifying at least one degree-two check node in the extended set of unsatisfied check nodes;
randomly selecting one variable node of two variable nodes connected to the at least one degree-two check node as the at least one candidate variable node for correction.

31. The method of claim 17, wherein the act E) includes an act of:
E1) seeding the at least one candidate variable node with a maximum-certainty likelihood value.

32. The method of claim 31, wherein the act E1) includes an act of:
replacing at least one channel-based likelihood provided as an input to the at least one candidate variable node with the maximum-certainty likelihood value.

33. The method of claim 32, further including an act of:
randomly selecting the maximum-certainty likelihood value.

34. The method of claim 32, further including an act of:
selecting the maximum-certainty likelihood value based at least in part on the channel-based likelihood value being replaced.

35. The method of claim 32, further including an act of:
selecting the maximum-certainty likelihood value based at least in part on a likelihood value present at the at least one candidate variable node.

36. The method of claim 8, wherein, if the act C) does not provide valid decoded information, the method further includes acts of:
F) selecting a different value for the at least one altered value; and
G) executing at least a second round of additional iterations of the iterative decoding algorithm using the different value for the at least one altered value.

37. The method of claim 8, wherein, if the act C) does not provide valid decoded information, the method further includes acts of:
F) altering at least one different value used by the iterative decoding algorithm; and
G) executing at least a second round of additional iterations of the iterative decoding algorithm using the at least one different altered value.

38. The method of claim 8, wherein if the act C) does not provide valid decoded information, the method further includes acts of:
F) performing one of the following:
selecting a different value for the at least one altered value; and
altering at least one different value used by the iterative decoding algorithm;
G) executing another round of additional iterations of the iterative decoding algorithm;
H) if the act G) does not provide valid decoded information, proceeding to act I; and
I) repeating the acts F), G) and H) for a predetermined number of additional rounds or until valid decoded information is provided, whichever occurs first.

39. The method of claim 8, further including acts of:
F) if the act C) provides valid decoded information, adding the valid decoded information to a list of valid decoded information;
G) performing one of the following:
selecting a different value for the at least one altered value; and
altering at least one different value used by the iterative decoding algorithm;
H) executing another round of additional iterations of the iterative decoding algorithm;
I) if the act H) provides valid decoded information, adding the valid decoded information to the list of valid decoded information;
J) repeating the acts G), H) and I) for a predetermined number of additional rounds; and
K) selecting from the list of valid decoded information an entry of valid decoded information that minimizes a Euclidian distance between the entry and the received information.

40. An apparatus for decoding received information that has been encoded using a coding scheme, the apparatus comprising:
a decoder block configured to execute an iterative decoding algorithm for a predetermined first number of iterations; and
at least one controller that, upon failure of the decoder block to provide valid decoded information after the predetermined first number of iterations of the iterative decoding algorithm, is configured to alter at least one value used by the iterative decoding algorithm and control the decoder block so as to execute at least a first round of additional iterations of the iterative decoding algorithm using the at least one altered value.

41. The apparatus of claim 40, wherein the apparatus is configured to receive the received information from a coding channel that includes at least one data storage medium.

42. The apparatus of claim 40, wherein the apparatus is configured to receive the received information from a coding channel that is configured for use in a wireless communication system.

43. The apparatus of claim 40, wherein the apparatus is configured to receive the received information from a coding channel that is configured for use in a satellite communication system.

44. The apparatus of claim 40, wherein the apparatus is configured to receive the received information from a coding channel that is configured for use in an optical communication system.

45. The apparatus of claim 40, wherein the iterative decoding algorithm is a message-passing algorithm.

46. The apparatus of claim 45, wherein the coding scheme is a low-density parity check (LDPC) coding scheme, and wherein the message-passing algorithm is a standard belief-propagation (BP) algorithm.

47. The apparatus of claim 45, wherein the message-passing algorithm is based on a bipartite graph for the coding scheme, and wherein:
the at least one controller includes seeding logic configured to alter at least one likelihood value associated with at least one variable node of the bipartite graph.

48. The apparatus of claim 47, wherein:
the at least one controller includes choice of variable nodes logic configured to select at least one candidate variable node of the bipartite graph for correction; and
the seeding logic is configured to seed the at least one candidate variable node with the at least one altered likelihood value.

49. The apparatus of claim 48, wherein:
the at least one controller includes parity-check nodes logic configured to determine a set of unsatisfied check nodes of the bipartite graph, the set including at least one unsatisfied check node; and
the choice of variable nodes logic is configured to select the at least one candidate variable node based at least in part on the set of unsatisfied check nodes.

50. The apparatus of claim 40, wherein the at least one controller is configured to select a different value for the at least one altered value and execute at least a second round of additional iterations of the iterative decoding algorithm using the different value for the at least one altered value if the decoder block does not provide valid decoded information after the first round of additional iterations.

51. The apparatus of claim 40, wherein the at least one controller is configured to alter at least one different value used by the iterative decoding algorithm and execute at least a second round of additional iterations of the iterative decoding algorithm using the at least one different altered value if the decoder block does not provide valid decoded information after the first round of additional iterations.

52. The apparatus of claim 40, wherein if the decoder block does not provide valid decoded information after the first round of additional iterations, the at least one controller is configured to:
A) perform one of the following:
select a different value for the at least one altered value; and
alter at least one different value used by the iterative decoding algorithm;
B) execute another round of additional iterations of the iterative decoding algorithm;
C) if another round of additional iterations does not provide valid decoded information, proceed to D); and
D) repeat A), B) and C) for a predetermined number of additional rounds or until valid decoded information is provided, whichever occurs first.

53. The apparatus of claim 40, wherein the at least one controller is configured to:
A) if the decoder block provides valid decoded information after the first round of additional iterations, add the valid decoded information to a list of valid decoded information;
B) perform one of the following:
select a different value for the at least one altered value; and
alter at least one different value used by the iterative decoding algorithm;
C) execute another round of additional iterations of the iterative decoding algorithm;
D) if another round of additional iterations provides valid decoded information, add the valid decoded information to the list of valid decoded information;
E) repeat A), B) and C) for a predetermined number of additional rounds; and
F) select from the list of valid decoded information an entry of valid decoded information that minimizes a Euclidian distance between the entry and the received information.
